(19) United States
(12) Patent Application Publication
(10) Pub. No.: US 2025/0096772 A1
(43) Pub. Date: Mar. 20, 2025

(54) Microacoustic Filter with an Acoustically-Decoupled Electrode Structure

(71) Applicant: RF360 Singapore Pte. Ltd., Singapore (SG)

(72) Inventors: Soeren Zimmermann, Munich (DE); Marc Konstantin Dietrich, Munich (DE); Willi Aigner, Moosinning (DE); Benno Blaschke, Munich (DE); Matthias Knapp, Munich (DE)

(21) Appl. No.: 18/470,200

(22) Filed: Sep. 19, 2023

(51) Int. Cl. H03H 9/205; H03H 3/02; H03H 9/13

(52) U.S. Cl. CPC H03H 9/205; H03H 3/02; H03H 9/131

(57) ABSTRACT

An apparatus is disclosed for implementing a microacoustic filter with an acoustically-decoupled electrode structure. In an example aspect, the apparatus includes the microacoustic filter with a piezoelectric layer, a substrate, and an electrode structure. The piezoelectric layer has a crystalline structure operative to laterally excite a plate mode. The electrode structure is positioned between the piezoelectric layer and the substrate and has a has a first surface that faces the piezoelectric layer. The microacoustic filter also includes at least one spacer extending from the substrate past a plane defined by the first surface of the electrode structure and towards the piezoelectric layer to form a cavity between the electrode structure and the piezoelectric layer.

### TECHNICAL FIELD

This disclosure relates generally to wireless transceivers and other components that employ filters and, more specifically, to a microacoustic filter with an electrode structure that is acoustically-decoupled from a piezoelectric layer of the microacoustic filter.

### BACKGROUND

Electronic devices use radio-frequency (RF) signals to communicate information. These radio-frequency signals enable users to talk with friends, download information, share pictures, remotely control household devices, and receive global positioning information. To transmit or receive the radio-frequency signals within a given frequency band, the electronic device may use filters to pass signals within the frequency band and to suppress (e.g., attenuate) jammers or noise having frequencies outside of the frequency band. It can be challenging, however, to design a filter that provides filtering for radio-frequency applications, including those that utilize frequencies above 2 gigahertz (GHz).

### SUMMARY

An apparatus is disclosed that implements a microacoustic filter with an acoustically-decoupled electrode structure. To acoustically decouple the electrode structure from a piezoelectric layer of the microacoustic filter, the piezoelectric layer is suspended “above” the electrode structure such that a cavity (or gap) forms between the piezoelectric layer and the electrode structure. This cavity substantially confines a plate mode of the microacoustic filter to the piezoelectric layer, which reduces acoustic losses into the substrate. Additionally, the cavity prevents the piezoelectric layer from becoming partially metallized. As such, the microacoustic filter can realize enhanced quality factors, power durability, temperature stability, and spurious-mode suppression compared to other microacoustic filters that are impacted by the parasitic effects associated with a partially-metallized piezoelectric layer. The acoustic decoupling also provides additional freedom in designing the microacoustic filter. This design freedom enables the electromechanical coupling, static capacitance, resonance frequency, and electrode structure material to be readily adjusted to achieve a target level of performance and/or compensate for other design choices.

In an example aspect, an apparatus for filtering is disclosed. The apparatus includes a microacoustic filter with a piezoelectric layer, a substrate, an electrode structure, and at least one spacer. The piezoelectric layer has a crystalline structure operative to laterally excite a plate mode. The electrode structure is positioned between the piezoelectric layer and the substrate. The electrode structure has a first surface that faces the piezoelectric layer. The at least one spacer extends from the substrate past a plane defined by the first surface of the electrode structure and towards the piezoelectric layer to form a cavity between the electrode structure and the piezoelectric layer.

In an example aspect, an apparatus for filtering is disclosed. The apparatus includes a microacoustic filter configured to generate a filtered signal from a radio-frequency signal. The microacoustic filter includes a substrate and means for producing a formed acoustic wave associated with a laterally-excited plate mode. The microacoustic filter also includes means for converting the radio-frequency signal to an acoustic wave and converting the formed acoustic wave into the filtered signal. The microacoustic filter additionally includes means for separating the means for producing from the means for converting by forming a cavity between the means for producing and the means for converting.

In an example aspect, a method for manufacturing a microacoustic filter with an acoustically-decoupled electrode structure is disclosed. The method includes providing a piezoelectric layer having a crystalline structure operative to laterally excite a plate mode. The method also includes providing a substrate. The method additionally includes an electrode structure between the piezoelectric layer and the substrate. The electrode structure has a surface that faces the piezoelectric layer. The method further includes providing one or more spacers extending from the substrate past a plane defined by the surface of the electrode structure and towards the piezoelectric layer to form a cavity between the electrode structure and the piezoelectric layer.

In an example aspect, a microacoustic filter is disclosed. The microacoustic filter includes a piezoelectric layer, a substrate, and an electrode structure. The piezoelectric layer has a crystalline structure operative to laterally excite a plate mode. The electrode structure is positioned between the piezoelectric layer and the substrate. The electrode structure has a surface that faces the piezoelectric layer and is physically separated by a gap from the piezoelectric layer.

### BRIEF DESCRIPTION OF DRAWINGS

FIG. 1 illustrates an example operating environment for operating a microacoustic filter with an acoustically-decoupled electrode structure.

FIG. 2 illustrates an example wireless transceiver including at least one microacoustic filter with an acoustically-decoupled electrode structure.

FIG. 3-1 illustrates example components of a microacoustic filter with an acoustically-decoupled electrode structure.

FIG. 3-2 illustrates example Euler angles that define an orientation of a piezoelectric layer of a microacoustic filter with an acoustically-decoupled electrode structure.

FIG. 4 illustrates a first example implementation of a microacoustic filter with an acoustically-decoupled electrode structure.

FIG. 5 illustrates example surfaces of elements of a microacoustic filter with an acoustically-decoupled electrode structure.

FIG. 6 illustrates example spacers of a microacoustic filter with an acoustically-decoupled electrode structure.

FIG. 7-1 illustrates a first example implementation of an acoustically-decoupled electrode structure.

FIG. 7-2 illustrates a second example implementation of an acoustically-decoupled electrode structure.

FIG. 8 illustrates a second example implementation of a microacoustic filter with an acoustically-decoupled electrode structure.

FIG. 9 is a flow diagram illustrating an example process for manufacturing a microacoustic filter with an acoustically-decoupled electrode structure.

### DETAILED DESCRIPTION

To transmit or receive radio-frequency signals within a given frequency band, an electronic device may use filters to pass signals within the frequency band and to suppress (e.g., attenuate) jammers or noise having frequencies outside of the frequency band. Electroacoustic devices (e.g., “acoustic filters”) can be used to filter high-frequency signals in many applications, such as those with frequencies that are greater than 100 megahertz (MHz). An acoustic filter is tuned to pass certain frequencies (e.g., frequencies within its passband) and attenuate other frequencies (e.g., frequencies that are outside of its passband). Using a piezoelectric material, the acoustic filter operates by transforming an electrical signal wave that is applied to an electrical conductor into an acoustic wave (e.g., an acoustic signal wave) that forms across the piezoelectric material. The acoustic wave is then converted back into an electrical filtered signal. The acoustic filter can include an electrode structure that transforms or converts between the electromagnetic and acoustic waves.

The acoustic wave features a velocity having a magnitude that is significantly less than that of a velocity of the electromagnetic wave. Generally, the magnitude of the propagation velocity of a wave is proportional to a size of a wavelength of the wave. Consequently, after conversion of the electrical signal wave into the acoustic signal wave, the wavelength of the acoustic signal wave is significantly smaller than the wavelength of the electrical signal wave. The resulting smaller wavelength of the acoustic signal wave enables filtering to be performed using a smaller filter device. This permits acoustic filters to be used in space-constrained devices, including portable electronic devices such as cellular phones. The acoustic filters can be referred to as microacoustic filters.

It can be challenging to design a microacoustic filter that can provide filtering for higher frequencies, such as those used with Wi-Fi® at 2.4 gigahertz (GHz), at 5 GHz frequencies, at greater than 5 GHz frequencies, at sub-6 GHz frequencies, at frequencies between 6 and 18 GHZ, and/or at frequencies greater than or equal to 10 GHz. In particular, it can be challenging to design a filter that is affordable and can realize a target level of performance in terms of resonance quality factors, electromechanical coupling, temperature coefficient of frequency (TCF), power durability, insertion loss, and spurious-mode suppression.

To address these challenges, some techniques implement laterally-excited plate-mode microacoustic filters. Compared to other types of microacoustic filters, such as bulk-acoustic-wave (BAW) filters, the laterally-excited plate-mode microacoustic filter can realize a target level of performance in terms of electromechanical coupling, insertion loss, and quality factors at the higher frequencies. Performance of these filters, however, can be negatively impacted by parasitic effects originating from the partially metallized piezoelectric material. In particular, current designs can experience degraded quality factors, power durability issues, temperature instability, and spurious-mode excitation.

To provide certain performance improvements, techniques for implementing a microacoustic filter with acoustically-decoupled electrodes are disclosed. To acoustically decouple the electrode structure from a piezoelectric layer of the microacoustic filter, the piezoelectric layer is suspended “above” the electrode structure such that a cavity (or gap) forms between the piezoelectric layer and the electrode structure. This cavity substantially confines a plate mode of the microacoustic filter to the piezoelectric layer, which reduces acoustic losses into the substrate. Additionally, the cavity prevents the piezoelectric layer from becoming partially metallized. As such, the microacoustic filter can realize enhanced quality factors, power durability, temperature stability, and spurious-mode suppression compared to other microacoustic filters that are impacted by the parasitic effects associated with a partially-metallized piezoelectric layer. The acoustic decoupling also provides additional freedom in designing the microacoustic filter. This design freedom enables electromechanical coupling, static capacitance, resonance frequency, and electrode structure material to be readily adjusted to achieve a target level of performance and/or compensate for other design choices.

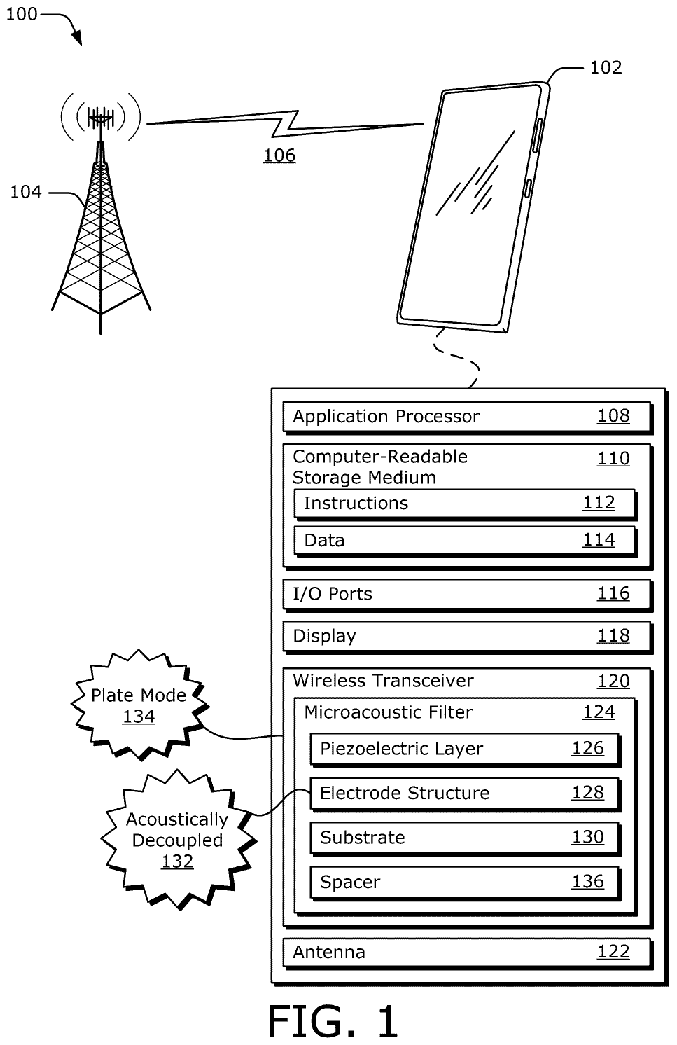

FIG. 1 illustrates an example environment 100 for operating a microacoustic filter with an acoustically-decoupled electrode structure. In the environment 100, a computing device 102 communicates with a base station 104 through a wireless communication link 106 (wireless link 106). In this example, the computing device 102 is depicted as a smartphone. However, the computing device 102 can be implemented as any suitable computing or electronic device, such as a modem, a cellular base station, a broadband router, an access point, a cellular phone, a gaming device, a navigation device, a media device, a laptop computer, a desktop computer, a tablet computer, a wearable computer, a server, a network-attached storage (NAS) device, a smart appliance or other internet of things (IoT) device, a medical device, a vehicle-based communication system, a radar, a radio apparatus, and so forth. Use of a microacoustic filter is not limited to wireless communication as a microacoustic filter can be applied in any technological field where such filtering is useful.

The base station 104 communicates with the computing device 102 via the wireless link 106, which can be implemented as any suitable type of wireless link. Although depicted as a tower of a cellular network, the base station 104 can represent or be implemented as another device, such as a satellite, a server device, a terrestrial television broadcast tower, an access point, a peer-to-peer device, a mesh network node, and so forth. Therefore, the computing device 102 may communicate with the base station 104 or another device via a wireless connection.

The wireless link 106 can include a downlink of data or control information communicated from the base station 104 to the computing device 102, an uplink of other data or control information communicated from the computing device 102 to the base station 104, or both a downlink and an uplink. The wireless link 106 can be implemented using any suitable communication protocol or standard, such as 2nd-generation (2G), 3rd-generation (3G), 4th-generation (4G), 5th-generation (5G), or 6th generation (6G) cellular; IEEE 802.11 (e.g., Wi-Fi®); IEEE 802.15 (e.g., Bluetooth®); IEEE 802.16 (e.g., WiMAX®); and so forth. In some implementations, the wireless link 106 may wirelessly provide power and the base station 104 or the computing device 102 may comprise a power source.

As shown, the computing device 102 includes an application processor 108 and a computer-readable storage medium 110 (CRM 110). The application processor 108 can include any type of processor, such as a multi-core processor, that executes processor-executable code stored by the CRM 110. The CRM 110 can include any suitable type of data storage media, such as volatile memory (e.g., random access memory (RAM)), non-volatile memory (e.g., Flash memory), optical media, magnetic media (e.g., disk), and so forth. In the context of this disclosure, the CRM 110 is implemented to store instructions 112, data 114, and other information of the computing device 102, and thus does not include transitory propagating signals or carrier waves.

The computing device 102 can also include input/output ports 116 (I/O ports 116) and a display 118. The I/O ports 116 enable data exchanges or interaction with other devices, networks, or users. The I/O ports 116 can include serial ports (e.g., universal serial bus (USB) ports), parallel ports, audio ports, infrared (IR) ports, user interface ports such as a touchscreen, and so forth. The display 118 presents graphics of the computing device 102, such as a user interface associated with an operating system, program, or application. Alternatively or additionally, the display 118 can be implemented as a display port or virtual interface, through which graphical content of the computing device 102 is presented.

A wireless transceiver 120 of the computing device 102 provides connectivity to respective networks and other electronic devices connected therewith. The wireless transceiver 120 can facilitate communication over any suitable type of wireless network, such as a wireless local area network (WLAN), peer-to-peer (P2P) network, mesh network, cellular network, ultra-wideband (UWB) network, wireless wide-area-network (WWAN), and/or wireless personal-area-network (WPAN). In the context of the example environment 100, the wireless transceiver 120 enables the computing device 102 to communicate with the base station 104 and networks connected therewith. However, the wireless transceiver 120 can also enable the computing device 102 to communicate “directly” with other devices or networks.

The wireless transceiver 120 includes circuitry and logic for transmitting and receiving communication signals via an antenna 122. Components of the wireless transceiver 120 can include amplifiers, switches, mixers, analog-to-digital converters, filters, and so forth for conditioning the communication signals (e.g., for generating or processing signals). The wireless transceiver 120 can also include logic to perform in-phase/quadrature (I/Q) operations, such as synthesis, encoding, modulation, decoding, demodulation, and so forth. In some cases, components of the wireless transceiver 120 are implemented as separate transmitter and receiver entities. Additionally or alternatively, the wireless transceiver 120 can be realized using multiple or different sections to implement respective transmitting and receiving operations (e.g., separate transmit and receive chains). In general, the wireless transceiver 120 processes data and/or signals associated with communicating data of the computing device 102 over the antenna 122.

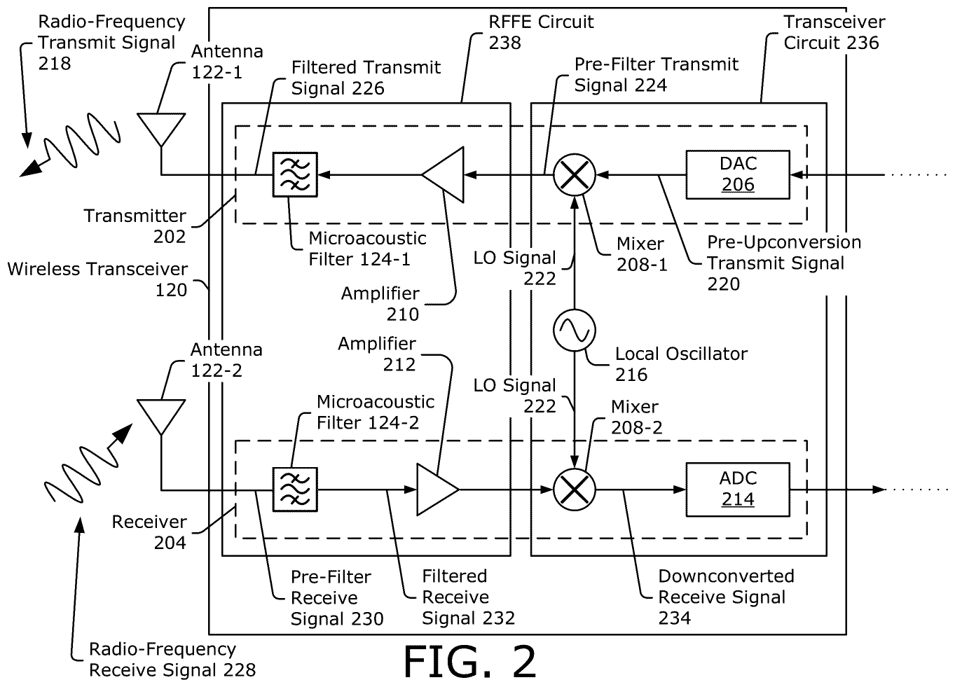

In the example shown in FIG. 1, the wireless transceiver 120 includes at least one microacoustic filter 124 (e.g., an acoustic filter, a plate-mode acoustic-wave filter, or a membrane-type filter). In some implementations, the wireless transceiver 120 includes multiple microacoustic filters 124, which can be formed from microacoustic resonators arranged in series, in parallel, in a ladder structure, in a lattice structure, or some combination thereof. The microacoustic filter 124 includes at least one piezoelectric layer 126, at least one electrode structure 128, and a substrate 130. It is possible to implement the substrate 130 as a single layer or as a substrate stack, as further described with respect to FIG. 2.

Although the microacoustic filter 124 can be any type of microacoustic filter, the techniques for implementing an electrode structure 128 that is acoustically-decoupled 132 can be particularly advantageous for confining an acoustic wave associated with a plate mode 134 within the piezoelectric layer 126 of the microacoustic filter 124. The plate mode 134 can be a first order antisymmetric Lamb mode (e.g., an A1 mode). Other order modes are also possible. The plate mode 134 can be referred to as a laterally-excited plate mode, as further explained below.

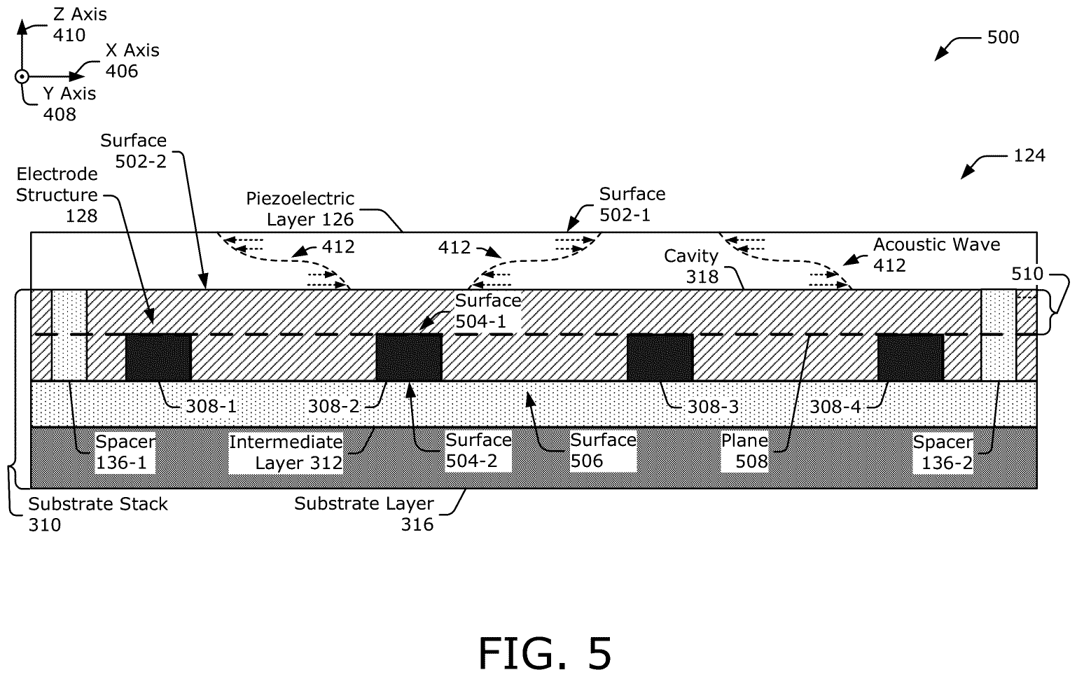

The piezoelectric layer 126 has a crystalline structure operative to laterally excite the plate mode 134. The laterally-excited plate mode 134 forms an acoustic wave that causes different portions (e.g., an upper portion and a lower portion) of the piezoelectric layer 126 to move in opposite directions along a horizontal dimension. In other words, the laterally-excited plate mode 134 causes displacement and elongation to occur along the horizontal dimension while propagation of the wavefronts occurs along a vertical dimension of the piezoelectric layer 126 as depicted with respect to FIG. 5. The wavefronts are vertically reflected at the free surface of the piezoelectric layer 126. The plate mode 134 is a quasi-stationary mode with approximately a zero group velocity in the lateral direction in the case of large pitches significantly exceeding a thickness of the piezoelectric layer 126.

The electrode structure 128 is positioned between the piezoelectric layer 126 and the substrate 130. To acoustically decouple 132 the electrode structure 128 from the piezoelectric layer 126, the microacoustic filter 124 includes at least one spacer 136, which suspends the piezoelectric layer 126 “above” or apart from the electrode structure 128. As such, the electrode structure 128 is, at least locally, physically separated from the piezoelectric layer 126 such that a cavity (or gap) exists between the electrode structure 128 and the piezoelectric layer 126. The cavity enables an acoustic wave to be confined within the piezoelectric layer 126. Furthermore, the cavity prevents the piezoelectric layer 126 from becoming partially metallized by the electrode structure 128.

With the techniques of acoustically decoupling the electrode structure 128, the microacoustic filter 124 can realize better performance than other types of plate-mode acoustic filters. In particular, the microacoustic filter 124 can realize enhanced quality factors, power durability, temperature stability, and spurious-mode suppression compared to other microacoustic filters that are impacted by the parasitic effects associated with a partially metallized piezoelectric layer. The acoustic decoupling also provides additional flexibility in designing the microacoustic filter 124. In particular, aspects of electromechanical coupling, static capacitance, resonance frequency, and electrode structure material can be readily adjusted to achieve a target level of performance and/or compensate for other design choices.

With these improvements, the microacoustic filter 124 can be designed to support frequency ranges above 2 GHZ, including frequencies between approximately 2 and 20 GHz. For example, the microacoustic filter 124 can be designed to have a resonance frequency between approximately 4 and 18 GHz, between approximately 7.5 and 17 GHz, or equal to approximately 4, 5, 6, 10, 13, 15, 17, or 20 GHz. In general, the term “approximately” can mean that any of the frequencies can be within +/−10% of a specified value or less (e.g., within +/−5%, +/−3%, or +/−2% of a specified value). The microacoustic filter 124 is further described with respect to FIG. 2.

FIG. 2 illustrates an example wireless transceiver 120. In the depicted configuration, the wireless transceiver 120 includes a transmitter 202 and a receiver 204, which are respectively coupled to a first antenna 122-1 and a second antenna 122-2. In other implementations, the transmitter 202 and the receiver 204 can be connected to a same antenna through a duplexer (not shown). The transmitter 202 is shown to include at least one digital-to-analog converter 206 (DAC 206), at least one first mixer 208-1, at least one amplifier 210 (e.g., a power amplifier), and at least one first microacoustic filter 124-1. The receiver 204 includes at least one second microacoustic filter 124-2, at least one amplifier 212 (e.g., a low-noise amplifier), at least one second mixer 208-2, and at least one analog-to-digital converter 214 (ADC 214). The first mixer 208-1 and the second mixer 208-2 are coupled to a local oscillator 216. Although not explicitly shown, the digital-to-analog converter 206 of the transmitter 202 and the analog-to-digital converter 214 of the receiver 204 can be coupled to the application processor 108 (of FIG. 1) or another processor associated with the wireless transceiver 120 (e.g., a modem).

In some implementations, the wireless transceiver 120 is implemented using multiple circuits (e.g., multiple integrated circuits), such as a transceiver circuit 236 and a radio-frequency front-end (RFFE) circuit 238. As such, the components that form the transmitter 202 and the receiver 204 are distributed across these circuits. As shown in FIG. 2, the transceiver circuit 236 includes the digital-to-analog converter 206 of the transmitter 202, the mixer 208-1 of the transmitter 202, the mixer 208-2 of the receiver 204, and the analog-to-digital converter 214 of the receiver 204. In other implementations, the digital-to-analog converter 206 and the analog-to-digital converter 214 can be implemented on another separate circuit that includes the application processor 108 or the modem. The radio-frequency front-end circuit 238 includes the amplifier 210 of the transmitter 202, the microacoustic filter 124-1 of the transmitter 202, the microacoustic filter 124-2 of the receiver 204, and the amplifier 212 of the receiver 204.

During transmission, the transmitter 202 generates a radio-frequency transmit signal 218, which is transmitted using the antenna 122-1. To generate the radio-frequency transmit signal 218, the digital-to-analog converter 206 provides a pre-upconversion transmit signal 220 to the first mixer 208-1. The pre-upconversion transmit signal 220 can be a baseband signal or an intermediate-frequency signal. The first mixer 208-1 upconverts the pre-upconversion transmit signal 220 using a local oscillator (LO) signal 222 provided by the local oscillator 216. The first mixer 208-1 generates an upconverted signal, which is referred to as a pre-filter transmit signal 224. The pre-filter transmit signal 224 can be a radio-frequency signal and include some noise or unwanted frequencies, such as a harmonic frequency. The amplifier 210 amplifies the pre-filter transmit signal 224 and passes the amplified pre-filter transmit signal 224 to the first microacoustic filter 124-1.

The first microacoustic filter 124-1 filters the amplified pre-filter transmit signal 224 to generate a filtered transmit signal 226. As part of the filtering process, the first microacoustic filter 124-1 attenuates the noise or unwanted frequencies within the pre-filter transmit signal 224. The transmitter 202 provides the filtered transmit signal 226 to the antenna 122-1 for transmission. The transmitted filtered transmit signal 226 is represented by the radio-frequency transmit signal 218.

During reception, the antenna 122-2 receives a radio-frequency receive signal 228 and passes the radio-frequency receive signal 228 to the receiver 204. The second microacoustic filter 124-2 accepts the received radio-frequency receive signal 228, which is represented by a pre-filter receive signal 230. The second microacoustic filter 124-2 filters any noise or unwanted frequencies within the pre-filter receive signal 230 to generate a filtered receive signal 232.

The amplifier 212 of the receiver 204 amplifies the filtered receive signal 232 and passes the amplified filtered receive signal 232 to the second mixer 208-2. The second mixer 208-2 downconverts the amplified filtered receive signal 232 using the local oscillator signal 222 to generate the downconverted receive signal 234. The analog-to-digital converter 214 converts the downconverted receive signal 234 into a digital signal, which can be processed by the application processor 108 or another processor associated with the wireless transceiver 120 (e.g., the modem).

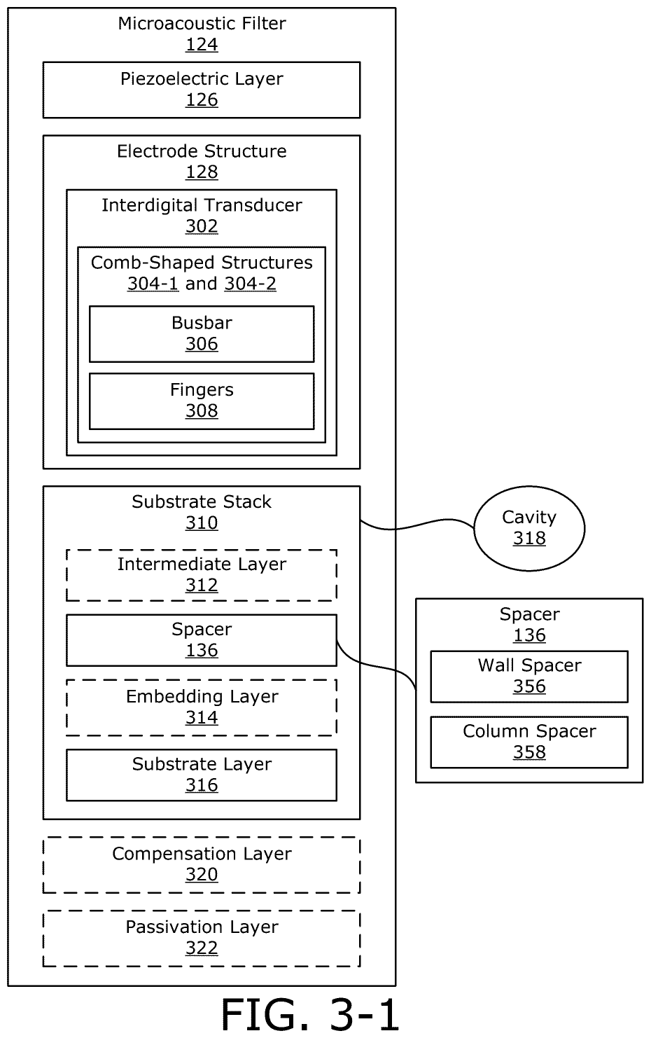

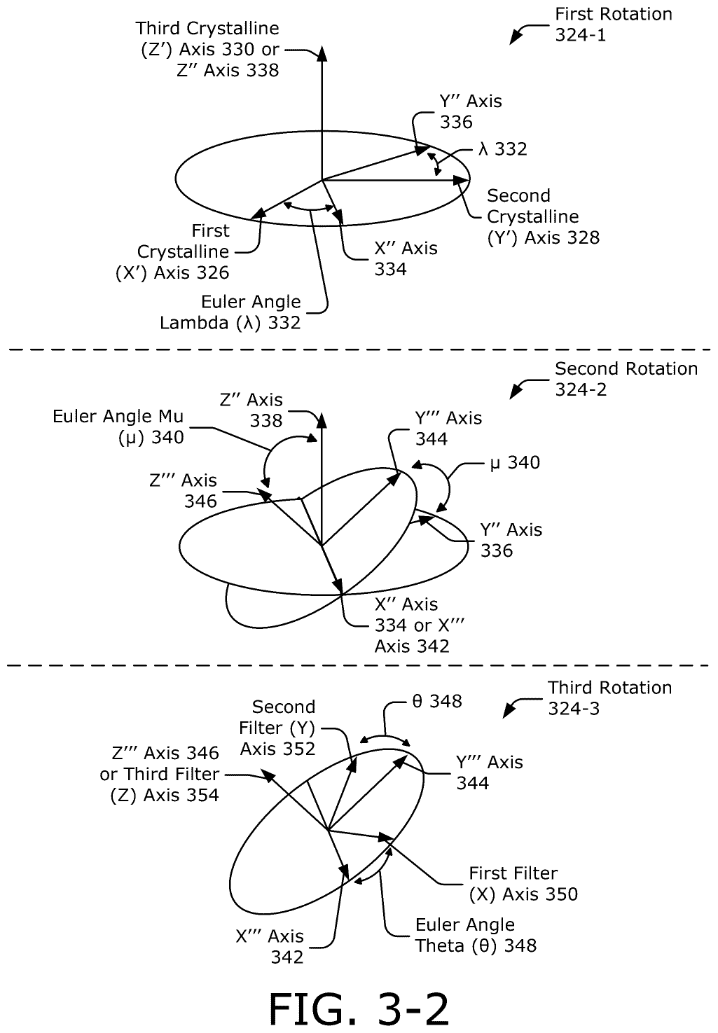

FIG. 2 illustrates one example configuration of the wireless transceiver 120. Other configurations of the wireless transceiver 120 can support multiple frequency bands and share an antenna 122 across multiple transceivers. One of ordinary skill in the art can appreciate the variety of other configurations for which microacoustic filters 124 may be included. For example, the microacoustic filters 124 can be integrated within duplexers or diplexers of the wireless transceiver 120. Example implementations of the microacoustic filter 124-1 or 124-2 are further described with respect to FIG. 3-1.

FIG. 3-1 illustrates example components of the microacoustic filter 124. In the depicted configuration, the microacoustic filter 124 includes the piezoelectric layer 126 and the electrode structure 128. In example implementations, the piezoelectric layer 126 can be implemented using a variety of different materials that exhibit piezoelectric properties (e.g., can transfer mechanical energy into electrical energy or electrical energy into mechanical energy). Example types of material include lithium niobate (LiNbO₃), lithium tantalate (LiTaO₃), or some combination thereof. In general, the material that forms the piezoelectric layer 126 may have a crystalline structure. This crystalline structure is defined by an ordered arrangement of particles (e.g., atoms, ions, or molecules). The orientation of the crystalline structure of the piezoelectric layer 126 can be defined by Euler angles lambda (λ), mu (μ), and theta (θ).

In some aspects, the material and crystalline structure of the piezoelectric layer 126 are selected such that the plate mode 134 can be laterally excited within the piezoelectric layer 126. Consider two examples in which the piezoelectric layer 126 is formed using lithium niobate. In a first example implementation, the lithium niobate material is cut such that a value of the Euler angle mu (μ) is approximately 32° and values of the Euler angles lambda (λ) and theta (θ) are approximately 0° (or at least one symmetrical equivalent thereof). In a second example implementation, the lithium niobate material is cut such that a value of the Euler angle theta (θ) is approximately 90° and values of the Euler angles lambda (λ) and mu (μ) are approximately zero (or at least one symmetrical equivalent thereof). In general, the term “approximately” can mean that any of the angles can be within ±10% of a specified value or less (e.g., within ±5%, ±3%, or ±2% of a specified value).

In another example, the piezoelectric layer 126 is formed using lithium tantalate. In this case, the lithium tantalate material is cut such that a value of the Euler angle mu (μ) is approximately 42° and values of the Euler angles lambda (2) and theta (θ) are approximately 0° (or at least one symmetrical equivalent thereof). In general, the term “approximately” can mean that any of the angles can be within +10% of a specified value or less (e.g., within +5%, +3%, or +2% of a specified value). The Euler angles are further described with respect to FIG. 3-2.

For the plate mode 134, a resonance frequency of the microacoustic filter 124 is determined, at least in part, by a thickness of the piezoelectric layer 126. To realize a resonance frequency between 4 and 15 GHz, the thickness of the piezoelectric layer 126 can be between approximately 100 and 400 nanometers (nm), for instance. Generally speaking, the thickness of the piezoelectric layer 126 and the resonance frequency are inversely related. In other words, decreasing the thickness of the piezoelectric layer 126 increases the resonance frequency of the microacoustic filter 124, while increasing the thickness of the piezoelectric layer 126 decreases the resonance frequency of the microacoustic filter 124.

The electrode structure 128 comprises an electrically conductive material, such as metal, and can include one or more layers. The one or more layers can include one or more electrically conductive layers and can optionally include one or more adhesion layers. As an example, the electrically conductive layers can be composed of aluminium (Al), copper (Cu), silver (Ag), gold (Au), tungsten (W), silicon (Si), or some combination or doped version thereof. The adhesion layers can be composed of chromium (Cr), titanium (Ti), molybdenum (Mo), or some combination thereof.

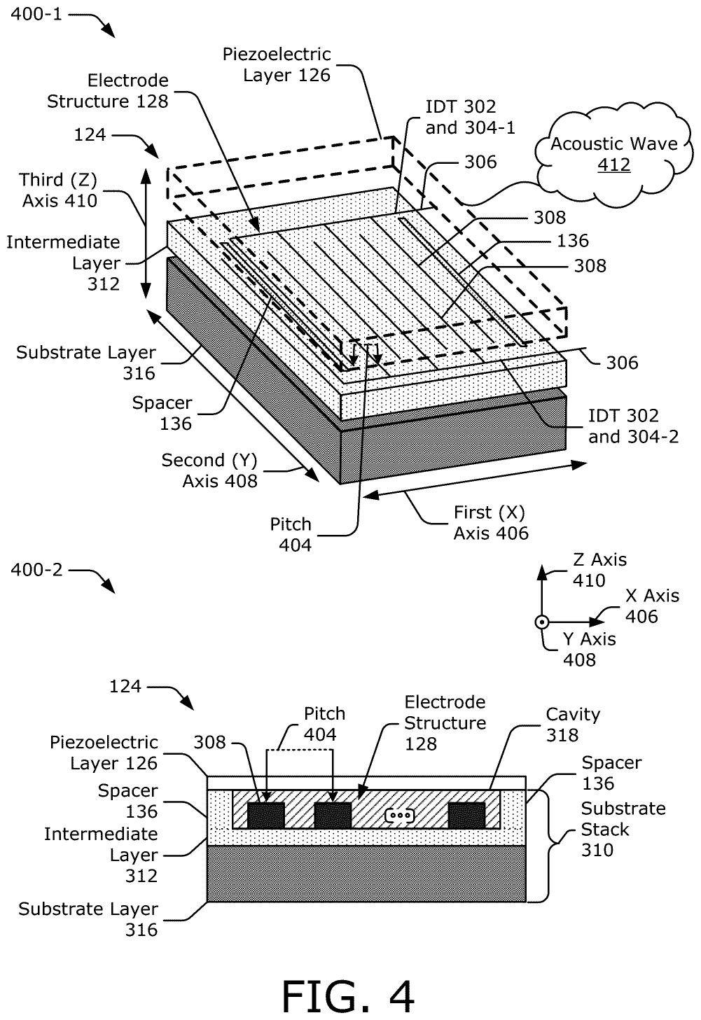

The electrode structure 128 can include one or more interdigital transducers 302. The interdigital transducer 302 converts an electrical signal into an acoustic wave and converts the acoustic wave into a filtered electrical signal. The interdigital transducer 302 includes at least two comb-shaped structures 304-1 and 304-2. Each comb-shaped structure 304-1 and 304-2 includes a busbar 306 (e.g., a conductive segment or rail) and multiple fingers 308 (e.g., electrode fingers). An example interdigital transducer 302 is further described with respect to FIG. 4. Although not explicitly shown, the electrode structure 128 can also include two or more reflectors. In an example implementation, the interdigital transducer 302 is arranged between two reflectors.

The microacoustic filter 124 also includes a substrate stack 310, which represents an example implementation of the substrate 130 of FIG. 1. The substrate stack 310 includes at least one optional intermediate layer 312, at least one spacer 136, an optional embedding layer 314, and at least one substrate layer 316. The intermediate layer 312 bonds the electrode structure 128 to the substrate layer 316 and functions as a foundation or base for the spacer 136. However, in another example, the spacer 136 may be part of the substrate 130 and the intermediate layer 312 is not necessary.

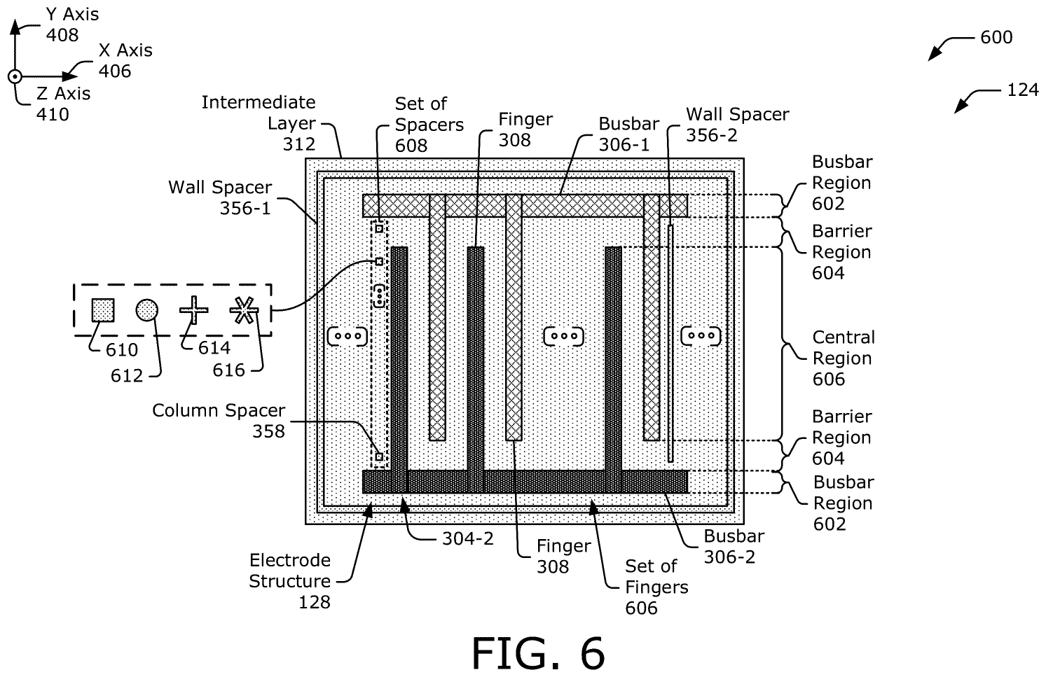

The spacer 136 provides structural support to elevate the piezoelectric layer 126 above the electrode structure 128. The spacer 136 can have a variety of different shapes and/or geometries. In some examples, the spacer 136 is implemented as a wall spacer 356, which has a longitudinal axis that is substantially parallel to a surface of the intermediate layer 312 (or the substrate 130). In other words, a longest dimension of the wall spacer 356 is positioned along a surface of the intermediate layer 312 (or the substrate 130). In other examples, the spacer 136 is implemented as a column spacer 358, which has a longitudinal axis that is substantially perpendicular to the surface of the intermediate layer 312 (or the substrate 130). Explained another way, a longest dimension of the column spacer 358 contributes to an overall height of the microacoustic filter 124. Example wall spacers 356 and column spacers 358 are further described with respect to FIG. 6. The spacer 136 can also be implemented by or considered as a pillar in some aspects.

In example implementations, the intermediate layer 312 and the spacer 136 are formed using a non-conductive material, such as amorphous silicon (a-Si) or a dielectric material such as silicon dioxide or silicon nitride. Some manufacturing processes can form the intermediate layer 312 (or the substrate 130) and the spacer 136 in separate steps. Other manufacturing processes can deposit a material that forms both the intermediate layer 312 and the spacer 136 in a single step. For instance, the spacer 136 may be formed from the intermediate layer 312 (or the substrate 130) using etching.

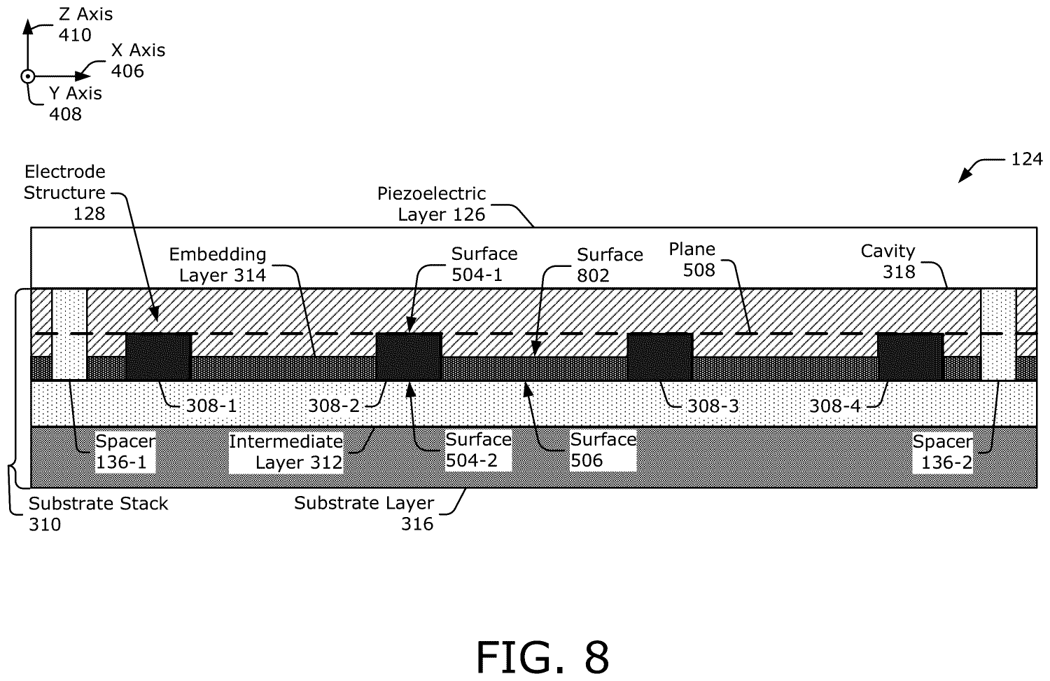

In general, the substrate stack 310 defines a cavity 318 (or gap) between the piezoelectric layer 126 and the electrode structure 128. The cavity 318 can include a gas, such as air. In some implementations, the cavity 318 is at least partially filled in by the embedding layer 314, as further described with respect to FIG. 8.

The embedding layer 314 can be formed using a dielectric material, which can be composed of a single material or multiple materials. Example dielectric materials include aluminium oxide (Al₂O₃), silicon dioxide (SiO₂), silicon nitride (Si₃N₄), and hafnium oxide (HfO₂). The dielectric material has a sufficiently high permittivity to enhance static capacitance and reduce a footprint of the microacoustic filter 124. Other implementations are also possible in which the substrate stack 310 does not include the embedding layer 314.

The substrate layer 316 is composed of material that is non-conducting and provides isolation. Example materials include silicon (Si), silicon dioxide (SiO₂), silicon carbide (SiC), sapphire, glass, or some combination or doped version thereof. In some implementations, the substrate layer 316 is composed of multiple layers. The multiple layers can be formed using the same material or different materials.

The microacoustic filter 124 can optionally include a compensation layer 320 and/or a passivation layer 322. The compensation layer 320 is disposed on the piezoelectric layer 126 and provides temperature compensation to enable the microacoustic filter 124 to achieve a target temperature coefficient of frequency based on the thickness of the piezoelectric layer 126. In example implementations, the compensation layer 320 can be formed using silicon dioxide (SiO₂), or some doped version thereof. Doped versions of silicon dioxide can include fluorine-doped silicon dioxide (e.g., SiOₓF_{y}) or carbon-doped silicon dioxide (e.g., SiOₓC_{y}). In some applications, the microacoustic filter 124 may not include, for instance, the compensation layer 320 to reduce cost of the microacoustic filter 124.

The passivation layer 322 can be disposed on the compensation layer 320 or the piezoelectric layer 126. In an example implementation, the passivation layer 322 is formed using silicon nitride (Si₃N₄). The passivation layer 322 can protect the underlying layer(s) from an external environment. The thickness of the passivation layer 322 can further be used to adjust the frequency of the microacoustic filter 124.

In some aspects, the microacoustic filter 124 can be considered a resonator. Sometimes the microacoustic filter 124 can be connected to other resonators associated with different layer stacks than the microacoustic filter 124. In other aspects, the microacoustic filter 124 can be implemented as multiple interconnected resonators, which use the same layers (e.g., the piezoelectric layer 126, the electrode structure 128, and/or the substrate stack 310).

Although not explicitly shown, the microacoustic filter 124 can also include other layers, such as an etch-stop layer, between the piezoelectric layer 126 and the cavity 318. This additional layer can protect the piezoelectric layer 126 during the manufacturing process. Aspects of the piezoelectric layer 126 are further described with respect to FIG. 3-2.

FIG. 3-2 illustrates example Euler angles that define an orientation of the piezoelectric layer 126 relative to a crystalline structure of the material that forms the piezoelectric layer 126. In this example, the material that forms the piezoelectric layer 126 includes lithium niobate and/or lithium tantalate. A first crystalline (X′) axis 326, a second crystalline (Y′) axis 328, and a third crystalline (Z′) axis 330 are fixed along crystallographic axes of a lithium niobate crystal. A first rotation 324-1 is applied to rotate the first crystalline X′ axis 326 and the second crystalline Y′ axis 328 about the third crystalline Z′ axis 330. In particular, the first rotation 324-1 rotates the first crystalline X′ axis 326 in a direction of the second crystalline Y′ axis 328. The angle associated with the first rotation 324-1 characterizes one of the Euler angles, which is represented by Euler angle lambda (2) 332. The resulting rotated axes are represented by a new set of axes: an X″ axis 334, a Y″ axis 336, and a Z″ axis 338. As shown in FIG. 3-2, the third crystalline Z′ axis 330 remains unchanged by the first rotation 324-1 such that the third crystalline Z′ axis 330 is equal to the Z″ axis 338.

In a second rotation 324-2, the Y″ axis 336 and the Z″ axis 338 are rotated about the X″ axis 334 by another Euler angle, which is represented by Euler angle mu (u) 340. In this case, the Y″ axis 336 is rotated in the direction of the Z″ axis 338. The resulting rotated axes are represented by a new set of axes: an X′″ axis 342, a Y′″ axis 344, and a Z′″ axis 346. As shown in FIG. 3-2, the X″ axis 334 remains unchanged by the second rotation 324-2 such that the X″ axis 334 is equal to the X′″ axis 342.

In a third rotation 324-3, the X′″ axis 342 and the Y′″ 344 axis are rotated about the Z′″ axis 346 by an additional Euler angle, which is represented by Euler angle theta (θ) 348. In this case, the X′″ axis 342 is rotated in the direction of the Y′″ axis 344. The resulting rotated axes are represented by a first filter (X) axis 350, a second filter (Y) axis 352, and a third filter (Z) axis 354, which respectively correspond to the first (X) axis 406, the second (Y) axis 408, and the third (Z) axis 410 of FIG. 4. As shown in FIG. 3-2, the Z′″ axis 346 remains unchanged by the third rotation 324-3 such that the Z′″ ′ axis 346 is equal to the third filter Z axis 354. The microacoustic filter 124 is further described with respect to FIG. 4.

FIG. 4 illustrates a first example implementation of the microacoustic filter 124 with the acoustically-decoupled electrode structure 128. A three-dimensional perspective view 400-1 of the microacoustic filter 124 is shown at the top of FIG. 4, and a two-dimensional cross-section view 400-2 of a portion of the microacoustic filter 124 is shown at the bottom of FIG. 4. The microacoustic filter 124 includes the piezoelectric layer 126, the electrode structure 128, and the substrate stack 310. The electrode structure 128 can include one or more interdigital transducers 302 (IDTs 302).

In the depicted configuration shown in the two-dimensional cross-section view 400-2, the intermediate layer 312 is disposed on the substrate layer 316 and the electrode structure 128 is disposed on the intermediate layer 312. The spacers 136 are disposed between the piezoelectric layer 126 and the intermediate layer 312. In various implementations, the spacers 136 can be positioned between the fingers 308 and the busbars 306 of the electrode structure 128, positioned in a manner that at least partially surrounds the electrode structure 128, or some combination thereof, as further described with respect to FIG. 6.

The spacers 136 elevate the piezoelectric layer 126 above the electrode structure 128 such that the cavity 318 forms between the piezoelectric layer 126 and the electrode structure 128. In this manner, the spacers 136, at least locally, physically separate the piezoelectric layer 126 from the electrode structure 128 such that the electrode structure 128 is not in direct physical contact with the piezoelectric layer 126. This separation acoustically decouples the electrode structure 128 from the piezoelectric layer 126.

In some cases, the cavity 318 can be considered a collection of multiple cavities that do not intersect. In other cases, the cavity 318 can be considered a single cavity with intersecting branches. The cavity is formed across at least a central region of the microacoustic filter 124, as further explained with respect to FIG. 6.

Disposing the electrode structure 128 on the intermediate layer 312 and “below” the piezoelectric layer 126 enables a surface of the piezoelectric layer 126 that faces away from the electrode structure 128 to be accessible for additional manufacturing processes. With the accessible surface of the piezoelectric layer 126, a trimming process can be performed to adjust a frequency response of the microacoustic filter 124. The trimming process, for instance, can reduce a thickness of the piezoelectric layer 126 to increase the resonance frequency of the microacoustic filter 124. In this way, acoustically-decoupling the electrode structure 128 from the piezoelectric layer 126 provides additional flexibility in manufacturing the microacoustic filter 124.

The acoustic decoupling also prevents a portion of the piezoelectric layer 126 from becoming metallized. In other microacoustic filters that have an electrode structure in physical contact with the piezoelectric layer, the metallization causes different regions of the piezoelectric layer to experience different electrical and/or mechanical loading. This causes dispersion mismatch, which can excite unwanted spurious modes. With acoustically decoupling, however, these spurious modes are at least significantly suppressed and, in some cases, no longer generated by the microacoustic filter 124.

In the three-dimensional perspective view 400-1, the interdigital transducer 302 is shown to have the two comb-shaped structures 304-1 and 304-2 with fingers 308 extending from two busbars 306 towards each other. The fingers 308 are arranged in an interlocking manner in between the two busbars 306 of the interdigital transducer 302 (e.g., arranged in an interdigitated manner). In other words, the fingers 308 connected to a first busbar 306 extend towards a second busbar 306 but do not connect to the second busbar 306. Likewise, fingers 308 connected to the second busbar 306 extend towards the first busbar 306 but do not connect to the first busbar 306.

In the direction along the busbars 306, there is an overlap region including a central region where a portion of one finger 308 overlaps with a portion of an adjacent finger 308. This central region, including the overlap, may be referred to as the aperture, track, or active region where electric fields are produced between fingers 308 to cause an acoustic wave 412 to form at least in this region of the piezoelectric layer 126.

A physical periodicity of the fingers 308 is referred to as a pitch 404 of the interdigital transducer 302. The pitch 404 may be indicated in various ways. For example, in certain aspects, the pitch 404 may correspond to a magnitude of a distance between adjacent fingers 308 of the interdigital transducer 302 in the central region. This distance may be defined, for example, as the distance between center points of each of the fingers 308. The distance may be generally measured between a right (or left) edge of one finger 308 and the right (or left) edge of an adjacent finger 308 when the fingers 308 have uniform widths. In certain aspects, an average of distances between adjacent fingers 308 of the interdigital transducer 302 may be used for the pitch 404. The pitch 404 can be determined to adjust the static capacitance and/or suppress spurious modes. The pitch 404 can also be determined to adjust the resonance frequency.

In the three-dimensional perspective view 400-1, the microacoustic filter 124 is defined by a first (X) axis 406, a second (Y) axis 408, and a third (Z) axis 410. The first axis 406 and the second axis 408 are parallel to a planar surface of the piezoelectric layer 126, and the second axis 408 is perpendicular to the first axis 406. The third (Z) axis 410 is normal (e.g., perpendicular) to the planar surface of the piezoelectric layer 126. The busbars 306 of the interdigital transducer 302 are oriented to be parallel to the first axis 406. The fingers 308 of the interdigital transducer 302 are orientated to be parallel to the second axis 408. The fingers 308 generate an electric field in a direction that is substantially parallel to the first axis 406. This electric field can excite a quasi-stationary acoustic wave 412, which is spatially trapped within the piezoelectric layer 126 and is present between adjacent fingers 308 of the electrode structure 128 as further described with respect to FIG. 5. Due to the crystalline structure of the piezoelectric layer 126 and the selected crystal cut, the lateral components of the electric field excite the plate mode 134 within the piezoelectric layer 126. Hence, the microacoustic filter 124 can be considered to operate with a laterally-excited plate mode 134.

During operation, the microacoustic filter 124 accepts a radio-frequency signal, such as the pre-filter transmit signal 224 or the pre-filter receive signal 230 shown in FIG. 2. The electrode structure 128 excites the acoustic wave 412 within the piezoelectric layer 126 using the inverse piezoelectric effect. For example, the interdigital transducer 302 in the electrode structure 128 generates an alternating electric field based on the accepted radio-frequency signal. The piezoelectric layer 126 enables the acoustic wave 412 to be formed in response to the alternating electric field generated by the interdigital transducer 302. In other words, the piezoelectric layer 126 causes, at least partially, the acoustic wave 412 to form responsive to electrical stimulation by one or more interdigital transducers 302.

The acoustic wave 412 forms within the piezoelectric layer 126 and interacts with the interdigital transducer 302 or another interdigital transducer within the electrode structure 128 (not shown in FIG. 4). The acoustic wave 412 that forms can be a standing wave. Using the piezoelectric effect, the electrode structure 128 generates a filtered radio-frequency signal based on the formed acoustic wave 412. In particular, the piezoelectric layer 126 generates an alternating electric field due to the mechanical stress generated by the acoustic wave 412. The alternating electric field induces an alternating current in the interdigital transducer 302. This alternating current forms the filtered radio-frequency signal, which is provided at an output of the microacoustic filter 124. The filtered radio-frequency signal can include the filtered transmit signal 226 or the filtered receive signal 232 of FIG. 2.

It should be appreciated that while a certain number of fingers are illustrated in FIG. 4, the number of actual fingers and lengths and width of the fingers and busbars may be different in an actual implementation. Such parameters depend on the particular application and desired filter characteristics. In addition, the microacoustic filter 124 can include multiple interconnected electrode structures 128 each including multiple interdigital transducers 302 to achieve a desired passband (e.g., multiple interconnected resonators or interdigital transducers 302 in series or parallel connections to form a desired filter transfer function).

Although not explicitly shown, the electrode structure 128 can also include two or more reflectors. In an example implementation, the interdigital transducer 302 is arranged between two reflectors (not shown). Each reflector within the electrode structure 128 can have two busbars and a grating structure of conductive fingers that each connect to both busbars. In some implementations, the pitch of the reflector can be similar to or the same as the pitch 404 of the interdigital transducer 302. The acoustic wave 412 is further described with respect to FIG. 5.

FIG. 5 illustrates a two-dimensional cross-section view 500 of a portion of the microacoustic filter 124, which includes the piezoelectric layer 126, the electrode structure 128, and the substrate stack 310. The piezoelectric layer 126 has a first surface 502-1 and a second surface 502-2, which is opposite the first surface 502-1. The first surface 502-1 faces away from the cavity 318, and the second surface 502-2 faces towards the cavity 318. In some implementations, the second surface 502-2 is exposed to the cavity 318 and defines a portion of the cavity 318. In other implementations not shown, another layer, such as an etch-stop layer or a passivation layer, is disposed on the second surface 502-2 of the piezoelectric layer 126. In this case, the other layer is exposed to the cavity 318 and defines the portion of the cavity 318.

The portion of the electrode structure 128 shown in FIG. 5 includes four fingers 308-1, 308-2, 308-3, and 308-4. The fingers 308-1 to 308-4 are positioned across the first (X) axis 406. The electrode structure 128 (including the fingers 308-1 to 308-4) has a first surface 504-1 and a second surface 504-2, which is opposite the first surface 504-1. The first surface 504-1 faces the piezoelectric layer 126 and is, at least locally, not in direct physical contact with the piezoelectric layer 126 or another layer that is disposed on the second surface 502-2 of the piezoelectric layer 126. The second surface 504-2 of the electrode structure 128 faces the intermediate layer 312 and the substrate layer 316. The second surface 504-2 of the electrode structure 128 can be in direct physical contact with the intermediate layer 312 in some implementations.

The portion of the substrate stack 310 shown in FIG. 5 includes two spacers 136-1 and 136-2, which are positioned across the first (X) axis 406. More specifically, the spacers 136-1 and 136-2 are positioned such that the four fingers 308-1 to 308-4 are between the spacers 136-1 and 136-2 across the first (X) axis 406. Although four fingers 308-1 to 308-4 are explicitly shown to be positioned between the spacers 136-1 and 136-2 in FIG. 5, it is to be understood that any quantity of fingers 308 can be positioned between the spacers 136-1 and 136-2.

In this example, the spacers 136-1 and 136-2 are disposed on a surface 506 of the intermediate layer 312 that faces the electrode structure 128. However, in another example, it is also possible that the substrate 130 itself provides the spacers 136-1 and 136-2. In general, a total thickness of the spacers 136-1 and 136-2 along the third (Z) axis 410 is greater than a thickness of the electrode structure 128. As such, the spacers 136-1 and 136-2 extend from the intermediate layer 312 (or the substrate 130) past a plane 508 defined by the first surface 504-1 of the electrode structure 128 and towards the piezoelectric layer 126. In this manner, the spacers 136-1 and 136-2 form the cavity 318 between the piezoelectric layer 126 and the electrode structure 128. The cavity 318 is at least partially defined by the second surface 502-2 of the piezoelectric layer 126 (or by another layer that is disposed on the second surface 502-2), the first surface 504-1 of the electrode structure 128, the surface 506 of the intermediate layer 312, and surfaces of the spacers 136-1 and 136-2.

With the spacers 136-1 and 136-2 elevating the piezoelectric layer 126 above the electrode structure 128, the electrode structure 128 is physically separated from the piezoelectric layer 126 by a gap 510. The gap 510 represents a distance between the first surface 504-1 of the electrode structure 128 and the second surface 502-2 of the piezoelectric layer 126. In some implementations, the distance of the gap 510 can be between approximately 2 and 200 nanometers. For example, the distance of the gap 510 can be between approximately 5 and 180 nm, between approximately 10 and 100 nm, or between approximately 50 and 75 nm. In general, the term “approximately” can mean that any of the distances can be within ±10% of a specified value or less (e.g., within ±5%, ±3%, or ±2% of a specified value).

The distance of the gap 510 is designed to enable the electrode structure 128 to be acoustically decoupled while also enabling the microacoustic filter 124 to realize a particular electromechanical coupling. The distance of the gap 510 and the electromechanical coupling are inversely related. Increasing the distance decreases the electromechanical coupling, and decreasing the distance increases the electromechanical coupling. One way to define the electromechanical coupling factor is further shown in Equation 1 below:

$${k}^{2} = \frac{{( \frac{π}{2} )}^{2} ( \frac{{f}_{s}}{{f}_{p}} ) ( {f}_{p} - {f}_{s} )}{{f}_{p}} \qquad Equation 1$$

where fₛ is the resonance frequency and fₚ is the antiresonance frequency. As an example, the electromechanical coupling factor of the microacoustic filter 124 can be between approximately 4% and 30%.

The distance of the gap 510 also impacts the static capacitance of the microacoustic filter 124. The distance and the static capacitance are inversely related. Increasing the distance decreases the static capacitance, and decreasing the distance increases the static capacitance. Some implementations of the microacoustic filter 124 can include the embedding layer 314, as shown in FIG. 8, to enable the microacoustic filter 124 to realize a target level of static capacitance. More specifically, a thickness of the embedding layer 314 can be designed to compensate for the decrease in the static capacitance caused by the gap 510.

Additionally, or alternatively, the pitch 404 and/or metallization ratio of the electrode structure 128 can be designed to enable the microacoustic filter 124 to realize the target level of static capacitance. The metallization ratio represents an average width of adjacent fingers divided by the pitch 404 and can be represented by the Greek letter eta (n). Decreasing the pitch 404 and/or increasing the metallization ratio can compensate for the impact of the gap 510 on the static capacitance. The acoustic decoupling of the electrode structure 128 also prevents the pitch 404 and/or the metallization ratio from contributing to the spurious modes of the microacoustic filter 124. In some implementations, values of the pitch 404 and/or the metallization ratio can be set to further suppress spurious modes.

During operation, the electrode structure 128 laterally excites the plate mode 134. The plate mode 134 is represented by the acoustic waves 412, which form within the piezoelectric layer 126. The acoustic waves 412 are positioned between adjacent pairs of fingers 308 that are coupled to different busbars 306-1 and 306-2 and associated with different polarities. The acoustic waves 412 propagate along the third (Z) axis 410, and causes displacement and elongation along the first (X) axis 406, as indicated by the arrows. The electrode structure 128 can be implemented in various ways, as further described with respect to FIGS. 6, 7-1, and 7-2.

FIG. 6 illustrates example spacers 136 of the microacoustic filter 124. A two-dimensional top-down view 600 of the microacoustic filter 124 depicts the electrode structure 128, the intermediate layer 312, and different types of spacers 136. For clarity, the piezoelectric layer 126 is not explicitly shown in FIG. 6.

The electrode structure 128 includes a first busbar 306-1, a second busbar 306-2, and multiple fingers 308. A portion of the fingers 308 are connected to the first busbar 306-1 and extend along the second (Y) axis 408 towards the second busbar 306-2 without connecting to the second busbar 306-2. These fingers 308 and the first busbar 306-1 form at least a portion of the first comb-shaped structure 304-1, which is illustrated using a diamond fill pattern.

Another portion of the fingers 308 are connected to the second busbar 306-2 and extend along the second (Y) axis 408 towards the first busbar 306-1 without connecting to the first busbar 306-1. These fingers 308 and the second busbar 306-2 form at least a portion of the second comb-shaped structure 304-2, which is illustrated using a fill pattern that has white dots on top of a dark background.

The microacoustic filter 124 includes multiple distinct regions along the second (Y) axis 408. These regions are defined, at least in part, based on a physical layout of the electrode structure 128. The regions include a busbar region 602, a barrier region 604, and a central region 606. The busbar region 602 includes the busbars 306-1 and 306-2 and extends along portions of the second (Y) axis 408 that correspond with the widths of the busbars 306-1 and 306-2. In this case, two busbar regions 602 are shown to be associated with the two busbars 306-1 and 306-2, respectively.

The barrier region 604 is present between the central region 606 and the busbar region 602. In particular, the barrier region 604 includes portions of the second (Y) axis 408 that extend between one busbar 306 and the ends of fingers 308 associated with another busbar 306 (e.g., an opposite busbar). For example, a first barrier region 604 exists between the first busbar 306-1 and the ends of fingers 308 connected to the second busbar 306-2. A second barrier region 604 exists between the second busbar 306-2 and ends of fingers 308 connected to the first busbar 306-1.

The central region 606 is defined by the overlap of fingers 308 across the first (X) axis 406. The central region 606 includes an active track region. The central region 606 can be associated with an acoustically-active resonator area of the microacoustic filter 124. The plate mode 134 of the microacoustic filter 124 is confined within the central region 606.

The microacoustic filter 124 can include multiple spacers 136. One type of spacer 136 includes a wall spacer 356, such as the first wall spacer 356-1 or the second wall spacer 356-2. The first wall spacer 356-1 is positioned around the electrode structure 128. Explained another way, the first wall spacer 356-1 includes segments that are positioned to the left and right of the electrode structure 128 along the first (X) axis 406, and segments that are positioned above and below the electrode structure 128 along the second (Y) axis 408. In this manner, the first wall spacer 356-1 can at least partially surround the electrode structure 128 and is positioned outside the acoustically-active resonator area of the microacoustic filter 124. The first wall spacer 356-1 of FIG. 6 is shown to include two horizontal segments and two vertical segments, which are connected together. Other implementations are also possible in which the first wall spacer 356-1 includes multiple horizontal and/or vertical segments that are disjoint or not connected together.

While the first wall spacer 356-1 is positioned outside of the acoustically-active resonator area, the microacoustic filter 124 can include other spacers 136 that are positioned within the acoustically-active resonator area, such as the second wall spacer 356-2 and/or the column spacer 358. In general, spacers 136 positioned within the acoustically-active resonator area (e.g., between the busbars 306-1 and 306-2 and between a left-most and right-most finger 308) can improve the mechanical stability of the microacoustic filter 124.

The second wall spacer 356-2 has a longitudinal axis that is parallel to the second (Y) axis 408 and the longitudinal axes of the fingers 308. A length of the second wall spacer 356-2 along the second (Y) axis 408 may or may not extend into the barrier region 604. Although not explicitly shown, the second wall spacer 356-2 can be positioned between two fingers 308 of the electrode structure 128.

In some implementations, a length of the second wall spacer 356-2 along the second (Y) axis 408 can be approximately equal to a length of a finger 308 (e.g., within ±10%, ±5%, ±3%, or ±2% of the length of the finger 308). In some cases, the length of the second wall spacer 356-2 is greater than the length of the finger 308. As such, the length of the second wall spacer 356-2 extends across the central region 606 and at least partially into the barrier region 604. In other cases, the length of the second wall spacer 356-2 along the second (Y) axis 408 is less than the length of the finger 308 but greater than half the length of the finger 308. A width of the second wall spacer 356-2 can be less than a width of the fingers 308 to avoid impacting the pitch 404 of the electrode structure 128.

Another type of spacer 136 is a column spacer 358, which can also be positioned within the acoustically-active resonator area. In this example, the microacoustic filter 124 includes a set of spacers 608, which includes multiple column spacers 358. The column spacers 358 within the set of spacers 608 are arranged along the second (Y) axis 408. Although the column spacers 358 are shown to be arranged in a straight line in FIG. 6, other non-linear arrangements are also possible. The column spacer 358 can have a variety of different shapes or geometries. For example, the top-down view of the column spacer 358 can be in the form of a rectangle 610, a circle 612, a cross 614, or a star 616.

The microacoustic filter 124 can be implemented with any combination of wall spacers 356 and/or column spacers 358. In one example implementation, the microacoustic filter 124 only includes the first wall spacer 356-1. In another example implementation, the microacoustic filter 124 includes the first wall spacer 356-1 and one or more other wall spacers 356 and/or column spacers 358 positioned at the edge of or within the acoustically-active resonator area. In yet another example implementation, the microacoustic filter 124 only includes wall spacers 356 and/or column spacers 358 within the acoustically-active resonator area.

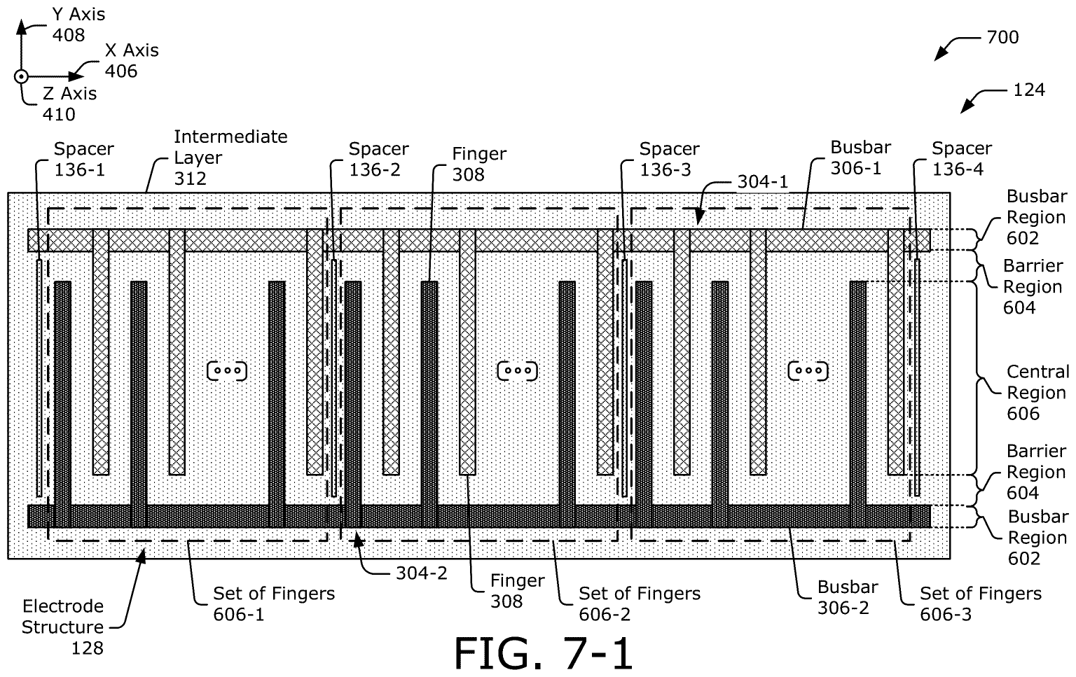

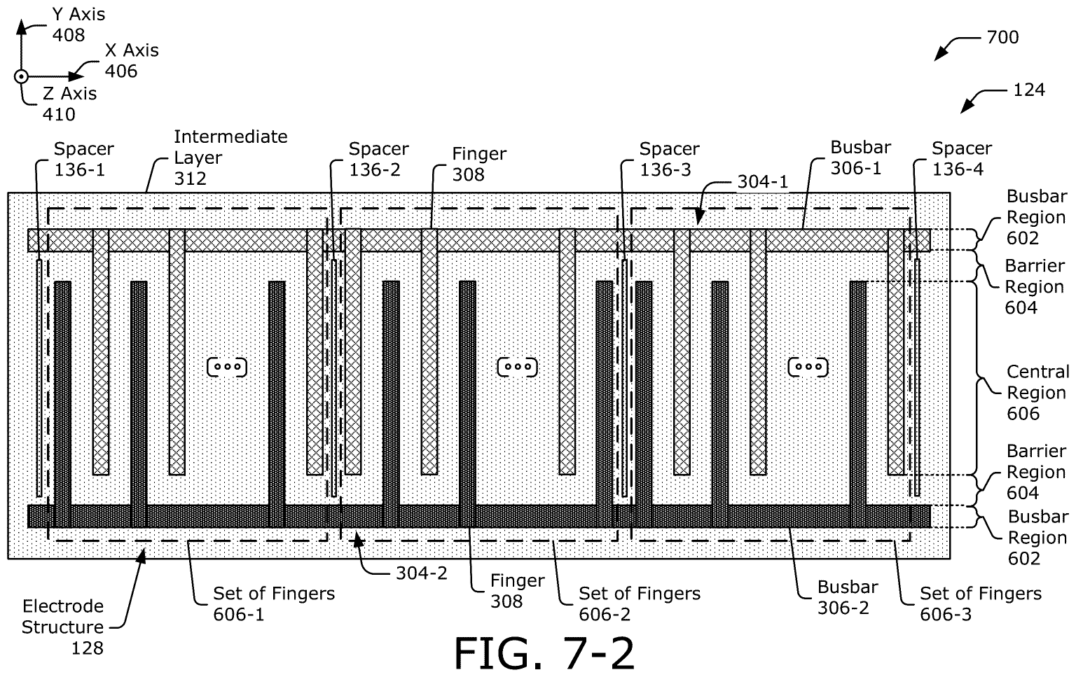

FIG. 7-1 illustrates a first example implementation of the electrode structure 128. In a two-dimensional top-down view 700, the microacoustic filter 124 is shown to include four spacers 136-1, 136-2, 136-3, and 136-4. Although the spacers 136 are illustrated as wall spacers 356 in FIG. 7-1, each spacer 136 can alternatively be implemented using one or more column spacers 358. At least some of the spacers 136 are positioned between adjacent fingers 308. For example, spacers 136-2 and 136-3 are positioned between different pairs of adjacent fingers 308. Other spacers 136 can be positioned at an edge of the microacoustic filter 124. For example, the spacer 136-1 can be positioned on a left side of the left-most finger 308 of the electrode structure 128, and the spacer 136-4 can be positioned on a right side of the right-most finger 308 of the electrode structure 128.

Different sets of fingers 308 are positioned between the spacers 136. For example, a first set of fingers 606-1 is positioned between the spacers 136-1 and 136-2. Likewise, a second set of fingers 606-2 is positioned between the spacers 136-2 and 136-3. Also, a third set of fingers 606-3 is positioned between the spacers 136-3 and 136-4. The sets of fingers 606-1 to 606-3 can include a same quantity of fingers 308 or different quantity of fingers 308. It can be convenient, especially for manufacturing purposes, to have the spacers 136 spaced at consistent distances across the first (X) axis 406. In some implementations, the quantity of spacers 136 is less than the quantity of fingers 308.

In the example electrode structure 128 shown in FIG. 7-1, the fingers 308 on either side of the spacers 136-2 and 136-3 are connected to different busbars 306-1 and 306-2 and have opposite polarities. In some microacoustic filter designs, this may be undesirable because an acoustic wave 412 can form within a region of the piezoelectric layer 126 that is above the spacers 136-2 and 136-3. In some cases, the spacers 136-2 and 136-3 can present a path for acoustic energy to travel to the intermediate layer 312, which can increase acoustic losses associated with the microacoustic filter 124. Alternatively, the electrode structure 128 can be implemented in a different manner, as further described with respect to FIG. 7-2.

FIG. 7-2 illustrates a second example implementation of the electrode structure 128. In the depicted configuration, the fingers 308 on either side of the spacers 136-2 and 136-3 are connected to a same busbar 306-1 or 306-2 and have a same polarity. In particular, the fingers 308 on either side of the spacers 136-2 are connected to the first busbar 306-1, and the fingers 308 on either side of the spacers 136-3 are connected to the second busbar 306-2. With the same polarities, the microacoustic filter 124 can avoid generating an electric field and exciting an acoustic wave 412 within a portion of the piezoelectric layer 126 that is above the spacers 136-2 and 136-3. This effectively prevents acoustic energy from leaking into the intermediate layer 312.

For clarity, the regions of the microacoustic filter 124 are not necessarily drawn to scale in FIGS. 6, 7-1, and 7-2. Further, each region may have some variability that deviates from the illustrated proportions or widths, including variabilities caused by constraints of a given manufacturing technology. One of ordinary skill in the art can appreciate that these dimensions can vary for other example implementations of the microacoustic filter 124. Another example implementation of the microacoustic filter 124 is further described with respect to FIG. 8.

FIG. 8 illustrates a second example implementation of the microacoustic filter 124 with an acoustically-decoupled electrode structure 128. While the cavity 318 enables the electrode structure 128 to be acoustically decoupled 132 from the piezoelectric layer 126, the larger separation distance between the electrode structure 128 and the piezoelectric layer 126 decreases the static capacitance of the microacoustic filter 124. To compensate for the smaller static capacitance, a microacoustic filter 124 can be designed with a larger footprint. However, a larger footprint can make it challenging to implement the microacoustic filter 124 within space-constrained devices.

To address this challenge, the microacoustic filter 124 can include the embedding layer 314 to enhance the static capacitance and reduce a footprint of the microacoustic filter 124. In some implementations, the cavity 318 formed by the one or more spacers 136 is at least partially filled by the embedding layer 314. In this manner, the embedding layer 314 is disposed between the intermediate layer 312 and the piezoelectric layer 126. The embedding layer 314 is also disposed between adjacent fingers 308 of the electrode structure 128 such that the electrode structure 128 is at least partially embedded within the embedding layer 314.

In some implementations, an entirety of the electrode structure 128 (e.g., the busbars 306 and the fingers 308) is at least partially embedded within the embedding layer 314. In other implementations, at least a portion of the electrode structure 128 that is within the central region 606 (e.g., a portion of the fingers 308) is at least partially embedded within the embedding layer 314.

In general, increasing a thickness of the embedding layer 314 increases the static capacitance of the microacoustic filter 124, and decreasing a thickness of the embedding layer 314 decreases the static capacitance of the microacoustic filter 124. The embedding layer 314 has a surface 802, which faces the piezoelectric layer 126. In some implementations, the surface 802 is “below” or “at” the plane 508 defined by the first surface 504-1 of the electrode structure 128. In other words, a thickness of the embedding layer 314 is less than or equal to a thickness of the electrode structure 128. In this case, the electrode structure 128 is partially buried within the embedding layer 314 such that the first surface 504-1 and/or portions of the sides of the electrode structure 128 are exposed and define a shape of the cavity 318.

In other implementations, the surface 802 of the embedding layer 314 is “above” the plane 508. As such, the thickness of the embedding layer 314 is greater than the thickness of the electrode structure 128. In this case, the electrode structure 128 is completely buried within the embedding layer 314 and defines part of the shape of the cavity 318 instead of the electrode structure 128. This can decrease the electromechanical coupling of the microacoustic filter 124, however. As such, the thickness of the embedding layer 314 can be designed to enable the microacoustic filter 124 to realize a particular static capacitance and electromechanical coupling.

In FIGS. 4 to 8, the electrode structure 128 is shown to be deposited on the surface 506 of the intermediate layer 312. Other implementations are also possible in which the electrode structure 128 is deposited on the substrate 130, partially embedded within the intermediate layer 312, or partially embedded within the substrate 130.

Dimensions of the layers, the spacer 136, and the electrode structure 128 shown in FIGS. 4 to 8 are not necessarily drawn to scale. Such parameters depend on the particular application and desired filter characteristics. One of ordinary skill in the art can appreciate the variety of configurations for which microacoustic filters 124 may be implemented.

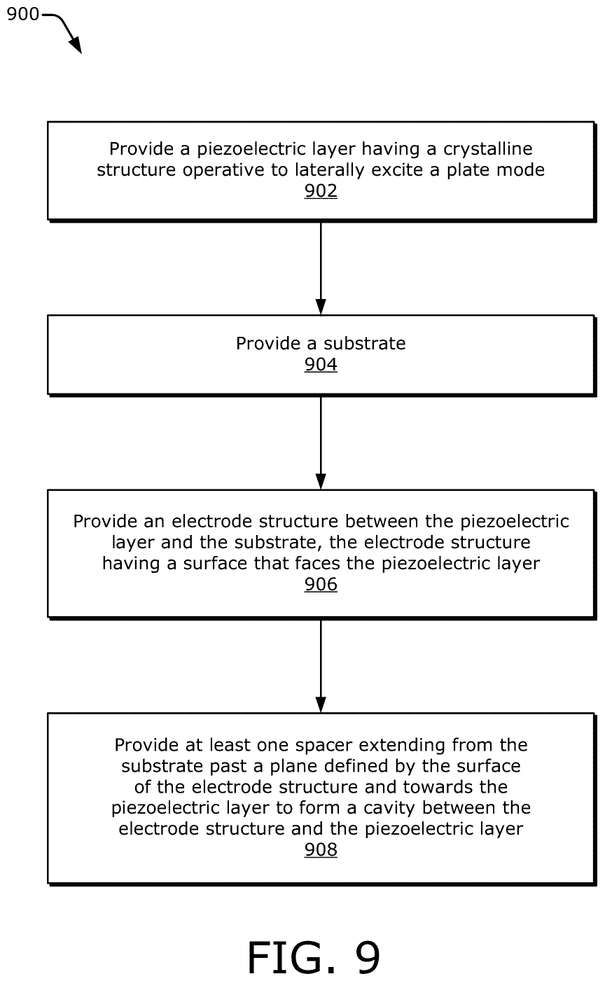

FIG. 9 is a flow diagram illustrating an example process 900 for manufacturing a microacoustic filter 124 with an acoustically-decoupled electrode structure. The process 900 is described in the form of a set of blocks 902-908 that specify operations that can be performed. However, operations are not necessarily limited to the order shown in FIG. 9 or described herein, for the operations may be implemented in alternative orders or in fully or partially overlapping manners. Also, more, fewer, and/or different operations may be implemented to perform the process 900, or an alternative process. Operations represented by the illustrated blocks of the process 900 may be performed to manufacture the microacoustic filter 124 (e.g., of FIGS. 1 to 3-1). More specifically, the operations of the process 900 may be performed, at least in part, to acoustically decouple 132 the electrode structure 128 from the piezoelectric layer 126 using one or more spacers 136 (e.g., of FIGS. 4 to 8).

At 902, a piezoelectric layer having a crystalline structure operative to laterally excite a plate mode is provided. For example, a manufacturing process provides the piezoelectric layer 126. The piezoelectric layer 126 has a crystalline structure operative to laterally excite the plate mode 134, as described with respect to FIGS. 4 and 5.

At 904, a substrate is provided. For example, the manufacturing process provides the substrate 130. The substrate 130 can be formed using a non-conductive material. In some implementations, the substrate 130 is implemented as a single layer. In other implementations, the substrate 130 is implemented as a substrate stack 310, which includes the intermediate layer 312 and the substrate layer 316. The intermediate layer 312 can bond the electrode structure 128 to the substrate layer 316.

At 906, an electrode structure is provided between the piezoelectric layer and the substrate. The electrode structure has a surface that faces the piezoelectric layer. For example, the manufacturing process provides (or disposes) the electrode structure 128 between the piezoelectric layer 126 and the substrate 130. In some implementations, the electrode structure 128 is directly disposed on the substrate 130. In other implementations, the electrode structure 128 is directly disposed on the intermediate layer 312 of the substrate stack 310. In the examples shown in FIGS. 4 to 8, the second surface of the electrode structure 128 is in direct physical contact with the intermediate layer 312. Other implementations are also possible in which the electrode structure 128 is partially embedded within the substrate 130 or is in direct physical contact with another layer that is disposed between the substrate 130 and the electrode structure 128. The electrode structure 128 has a first surface 504-1 that faces the piezoelectric layer 126, as shown in FIG. 5.

At 908, at least one spacer extends from the substrate past a plane defined by the surface of the electrode structure and towards the piezoelectric layer to form a cavity between the electrode structure and the piezoelectric layer. For example, the manufacturing process provides (e.g., disposes) one or more spacers 136 that extend from the substrate 130 past the plane 508 defined by the first surface 504-1 of the electrode structure 128 and towards the piezoelectric layer 126 to form the cavity 318 between the electrode structure 128 and the piezoelectric layer 126. The spacer 136 can be in direct physical contact with the substrate 130. Other implementations are also possible in which the spacer 136 is in direct physical contact with another layer that is disposed between the substrate 130 and the spacer 136. In other implementations, it is also possible that the spacer 136 is directly formed from the substrate 130.

There are various processes for implementing the microacoustic filter 124. In a first example, the manufacturing process embeds the electrode structure 128 within the substrate 130 (or within the intermediate layer 312 of the substrate stack 310). To start, the manufacturing process deposits a sacrificial material on top of a portion of the piezoelectric layer 126. The sacrificial material is not deposited in regions reserved for the spacer 136. Next, the manufacturing process deposits the electrode structure 128 on the sacrificial material. Next, the manufacturing process deposits a layer of material across the piezoelectric layer 126, the sacrificial material, and the electrode structure 128. This layer of material forms at least a portion of the substrate stack 310 and the spacer 136. The rest of the substrate stack is bonded to the existing portion of the substrate stack 310.

At this point, the stack can be flipped so that the piezoelectric layer 126 is on top. Next, a release hole is formed within the piezoelectric layer 126 to the sacrificial material. Lastly, the manufacturing process removes the sacrificial material using the release hole. By removing the sacrificial material, the cavity 318 forms between the electrode structure 128 and the piezoelectric layer 126.

In a second example, the manufacturing process uses a freestanding electrode structure 128. To start, the manufacturing process deposits the electrode structure 128 on the substrate 130 (or on the intermediate layer 312 of the substrate stack 310). Next, the manufacturing process deposits a sacrificial material on top of the electrode structure 128 and the intermediate layer 312. The sacrificial material is at least partially etched away to create space for the spacer 136. Next, the spacer 136 is disposed on the substrate 130. The piezoelectric layer 126 is then disposed across the spacer 136 and the sacrificial material. Next, release holes are etched within the piezoelectric layer 126 to the sacrificial material. Lastly, the manufacturing process removes the sacrificial material using the release hole. By removing the sacrificial material, the cavity 318 forms between the electrode structure 128 and the piezoelectric layer 126.

Although not explicitly described, the manufacturing processes described above can also include cleaning, bonding, grinding, polishing, selectively etching, and trimming one or more layers of the microacoustic filter 124. Also, the manufacturing processes can include additional steps of depositing an etch-stop layer, a compensation layer 320, a passivation layer 322, or some combination thereof.

The manufacturing processes described above enable the microacoustic filter 124 to be implemented with an acoustically decoupled electrode structure 128. The acoustic decoupling enables the microacoustic filter 124 to realize enhanced quality factors, power durability, temperature stability, and spurious-mode suppression compared to other microacoustic filters that are impacted by the parasitic effects associated with a partially-metallized piezoelectric layer. The acoustic decoupling also provides additional freedom in designing the microacoustic filter 124. In particular, aspects of electromechanical coupling, static capacitance, resonance frequency, and electrode structure material can be readily adjusted to achieve a target level of performance and/or compensate for other design choices.

Some aspects are described below.

Aspect 1: An apparatus comprising:
a microacoustic filter comprising:
   a piezoelectric layer having a crystalline structure operative to laterally excite a plate mode;
   a substrate;
   an electrode structure positioned between the piezoelectric layer and the substrate, the electrode structure having a first surface that faces the piezoelectric layer; and
   at least one spacer extending from the substrate past a plane defined by the first surface of the electrode structure and towards the piezoelectric layer to form a cavity between the electrode structure and the piezoelectric layer.

Aspect 2: The apparatus of aspect 1, wherein a distance between the first surface of the electrode structure and the piezoelectric layer is between approximately 2 and 200 nanometers.

Aspect 3: The apparatus of aspect 2, wherein the distance between the first surface of the electrode structure and the piezoelectric layer is between approximately 50 and 75 nanometers.

Aspect 4: The apparatus of any previous aspect, wherein the cavity is formed within at least an acoustically-active resonator area of the microacoustic filter.

Aspect 5: The apparatus of aspect 4, wherein the at least one spacer is positioned within the acoustically-active resonator area of the microacoustic filter.

Aspect 6: The apparatus of aspect 5, wherein:
the electrode structure comprises multiple fingers; and
the at least one spacer comprises multiple spacers positioned between different sets of fingers of the multiple fingers.

Aspect 7: The apparatus of aspect 6, wherein:
the electrode structure comprises two busbars; and
each spacer of the multiple spacers is positioned between two fingers of the multiple fingers that are connected to a same busbar of the two busbars.

Aspect 8: The apparatus of aspect 6, wherein:
the electrode structure comprises two busbars; and
each spacer of the multiple spacers is positioned between two fingers of the multiple fingers that are connected to different busbars of the two busbars.

Aspect 9: The apparatus of any one of aspects 5 to 8, wherein the at least one spacer comprises at least one wall spacer having a longitudinal axis that extends across at least a portion of the acoustically-active resonator area of the microacoustic filter.

Aspect 10: The apparatus of any one of aspects 5 to 9, wherein the at least one spacer comprises at least one column spacer.

Aspect 11: The apparatus of aspect 4, wherein the at least one spacer is positioned outside of the acoustically-active resonator area of the microacoustic filter.

Aspect 12: The apparatus of aspect 11, wherein the at least one spacer comprises at least one wall spacer that at least partially surrounds the electrode structure.

Aspect 13: The apparatus of any previous aspect, wherein:
the substrate comprises a substrate stack comprising an intermediate layer having a surface that faces a second surface of the electrode structure; and
the intermediate layer and the at least one spacer comprise a dielectric material or amorphous silicon.

Aspect 14: The apparatus of aspect 13, wherein:
the substrate stack comprises a substrate layer; and
the intermediate layer is disposed between the electrode structure and the substrate layer.

Aspect 15: The apparatus of aspect 14, wherein the substrate layer comprises at least one of the following materials:
silicon;
silicon dioxide;
silicon carbide;
sapphire; or
glass.

Aspect 16: The apparatus of any previous aspect, wherein the microacoustic filter comprises an embedding layer disposed on the substrate between adjacent fingers of multiple fingers of the electrode structure such that the electrode structure is at least partially embedded within the embedding layer.

Aspect 17: The apparatus of aspect 16, wherein a thickness of the embedding layer is less than or equal to a thickness of the electrode structure.

Aspect 18: The apparatus of aspect 16 or 17, wherein the embedding layer comprises a dielectric material.

Aspect 19: The apparatus of any previous aspect, wherein:
multiple fingers of the electrode structure are positioned across a first axis;
longitudinal axes of the multiple fingers are substantially parallel to a second axis that is perpendicular to the first axis;
a third axis is perpendicular to the first axis and the second axis;
an orientation of the first axis, the second axis, and the third axis is relative to a crystalline structure of the piezoelectric layer as defined by Euler angles lambda, mu, and theta; and
the piezoelectric layer comprises lithium niobate with a value of the Euler angle lambda being approximately 0°, a value of the Euler angle mu being approximately 32°, and a value of the Euler angle theta being approximately 0°, or at least one symmetrical equivalent thereof.

Aspect 20: The apparatus of any previous aspect, wherein:
multiple fingers of the electrode structure are positioned across a first axis;
longitudinal axes of the multiple fingers are substantially parallel to a second axis that is perpendicular to the first axis;
a third axis is perpendicular to the first axis and the second axis;
an orientation of the first axis, the second axis, and the third axis is relative to a crystalline structure of the piezoelectric layer as defined by Euler angles lambda, mu, and theta; and
the piezoelectric layer comprises lithium niobate with the value of the Euler angle lambda being approximately 0°, the value of the Euler angle mu being approximately 0°, and the value of the Euler angle theta being approximately 90°, or at least one symmetrical equivalent thereof.

Aspect 21: The apparatus of any previous aspect, wherein:
multiple fingers of the electrode structure are positioned across a first axis;
longitudinal axes of the multiple fingers are substantially parallel to a second axis that is perpendicular to the first axis;
a third axis is perpendicular to the first axis and the second axis;
an orientation of the first axis, the second axis, and the third axis is relative to a crystalline structure of the piezoelectric layer as defined by Euler angles lambda, mu, and theta; and
the piezoelectric layer comprises lithium tantalate with a value of the Euler angle lambda being approximately 0°, a value of the Euler angle mu being approximately 42°, and a value of the Euler angle theta being approximately 0°, or at least one symmetrical equivalent thereof.

Aspect 22: The apparatus of any previous aspect, wherein:
the cavity is at least partially filled with a gas; and
the gas comprises air.

Aspect 23: The apparatus of any previous aspect, wherein a resonance frequency associated with the plate mode is between approximately 2 and 20 gigahertz.

Aspect 24: The apparatus of aspect 23, wherein the resonance frequency associated with the plate mode is between approximately 7.5 and 17 gigahertz.

Aspect 25: The apparatus of any previous aspect, wherein:
the microacoustic filter comprises multiple cascaded resonators; and
a resonator of the multiple cascaded resonators comprises the piezoelectric layer, the electrode structure, and the substrate.

Aspect 26: The apparatus of aspect 1, further comprising:
a wireless transceiver coupled to at least one antenna, the wireless transceiver comprising the microacoustic filter and configured to filter, using the microacoustic filter, a wireless signal communicated via the at least one antenna.

Aspect 27: An apparatus comprising:
a microacoustic filter configured to generate a filtered signal from a radio-frequency signal, the microacoustic filter comprising:
   a substrate;
   means for producing a formed acoustic wave associated with a laterally-excited plate mode;
   means for converting the radio-frequency signal to an acoustic wave and converting the formed acoustic wave into the filtered signal; and
   means for separating the means for producing from the means for converting by forming a cavity between the means for producing and the means for converting.

Aspect 28: The apparatus of aspect 27, wherein the microacoustic filter comprises means for bonding the means for converting to the substrate.

Aspect 29: The apparatus of aspect 27 or 28, wherein the microacoustic filter comprises means for compensating for a decrease in a static capacitance associated with a separation distance between the means for producing and the means for converting, the means for compensating at least partially embedding the means for converting.

Aspect 30: A method of manufacturing a microacoustic filter, the method comprising:
providing a piezoelectric layer having a crystalline structure operative to laterally excite a plate mode;
providing a substrate;
providing an electrode structure between the piezoelectric layer and the substrate, the electrode structure having a surface that faces the piezoelectric layer; and
providing at least one spacer extending from the substrate past a plane defined by the surface of the electrode structure and towards the piezoelectric layer to form a cavity between the electrode structure and the piezoelectric layer.

Aspect 31: The method of aspect 30, further comprising:
providing a dielectric material between the substrate and the piezoelectric layer, the dielectric material at least partially embedding the electrode structure.

Aspect 32: A microacoustic filter comprising:
a piezoelectric layer having a crystalline structure operative to laterally excite a plate mode;
a substrate; and
an electrode structure that is positioned between the piezoelectric layer and the substrate, the electrode structure having a surface that faces the piezoelectric layer and is separated by a gap from the piezoelectric layer.

Aspect 33: The microacoustic filter of aspect 32, wherein a distance between the surface of the electrode structure and the piezoelectric layer is between approximately 2 and 200 nanometers.

Aspect 34: The microacoustic filter of aspect 32 or 33, further comprising:
an intermediate layer disposed between the electrode structure and the substrate, the intermediate layer comprising amorphous silicon or a dielectric.

Aspect 35: The microacoustic filter of aspect 34, wherein:
the microacoustic filter comprises at least one spacer disposed on the intermediate layer, the at least one spacer extending past a plane defined by the surface of the electrode structure; and
the at least one spacer comprises the amorphous silicon or the dielectric.

Aspect 36: The microacoustic filter of aspect 35, wherein:
the electrode structure comprises two busbars and multiple fingers; and
the at least one spacer is positioned between two fingers of the multiple fingers, the two fingers connected to a same busbar of the two busbars.

Aspect 37: The microacoustic filter of any one of aspects 32 to 36, further comprising a dielectric material positioned between the substrate and the piezoelectric layer and at least partially embedding the electrode structure.

Aspect 38: The microacoustic filter of any one of aspects 32 to 37, wherein:
the electrode structure comprises multiple fingers positioned across a first axis;
longitudinal axes of the multiple fingers are substantially parallel to a second axis that is perpendicular to the first axis;
a third axis is perpendicular to the first axis and the second axis;
an orientation of the first axis, the second axis, and the third axis is relative to the crystalline structure of the piezoelectric layer as defined by Euler angles lambda, mu, and theta; and
the piezoelectric layer comprises one of the following:
   lithium niobate with a value of the Euler angle lambda being approximately 0°, a value of the Euler angle mu being approximately 32°, and a value of the Euler angle theta being approximately 0°, or at least one symmetrical equivalent thereof;
   the lithium niobate with the value of the Euler angle lambda being approximately 0°, the value of the Euler angle mu being approximately 0°, and the value of the Euler angle theta being approximately 90°, or at least one symmetrical equivalent thereof; or
   lithium tantalate with a value of the Euler angle lambda being approximately 0°, a value of the Euler angle mu being approximately 42°, and a value of the Euler angle theta being approximately 0°, or at least one symmetrical equivalent thereof.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). Further, items represented in the accompanying figures and terms discussed herein may be indicative of one or more items or terms, and thus reference may be made interchangeably to single or plural forms of the items and terms in this written description. Finally, although subject matter has been described in language specific to structural features or methodological operations, it is to be understood that the subject matter defined in the appended claims is not necessarily limited to the specific features or operations described above, including not necessarily being limited to the organizations in which features are arranged or the orders in which operations are performed.

What is claimed is:

1. An apparatus comprising:
a microacoustic filter comprising:
a piezoelectric layer having a crystalline structure operative to laterally excite a plate mode;
a substrate;
an electrode structure positioned between the piezoelectric layer and the substrate, the electrode structure having a first surface that faces the piezoelectric layer; and
at least one spacer extending from the substrate past a plane defined by the first surface of the electrode structure and towards the piezoelectric layer to form a cavity between the electrode structure and the piezoelectric layer.

2. The apparatus of claim 1, wherein a distance between the first surface of the electrode structure and the piezoelectric layer is between approximately 2 and 200 nanometers.

3. The apparatus of claim 2, wherein the distance between the first surface of the electrode structure and the piezoelectric layer is between approximately 50 and 75 nanometers.

4. The apparatus of claim 1, wherein the cavity is formed within at least an acoustically-active resonator area of the microacoustic filter.

5. The apparatus of claim 4, wherein the at least one spacer is positioned within the acoustically-active resonator area of the microacoustic filter.

6. The apparatus of claim 5, wherein:
the electrode structure comprises multiple fingers; and
the at least one spacer comprises multiple spacers positioned between different sets of fingers of the multiple fingers.

7. The apparatus of claim 6, wherein:
the electrode structure comprises two busbars; and
each spacer of the multiple spacers is positioned between two fingers of the multiple fingers that are connected to a same busbar of the two busbars.

8. The apparatus of claim 6, wherein:
the electrode structure comprises two busbars; and
each spacer of the multiple spacers is positioned between two fingers of the multiple fingers that are connected to different busbars of the two busbars.

9. The apparatus of claim 5, wherein the at least one spacer comprises at least one wall spacer having a longitudinal axis that extends across at least a portion of the acoustically-active resonator area of the microacoustic filter.

10. The apparatus of claim 5, wherein the at least one spacer comprises at least one column spacer.

11. The apparatus of claim 4, wherein the at least one spacer is positioned outside of the acoustically-active resonator area of the microacoustic filter.

12. The apparatus of claim 11, wherein the at least one spacer comprises at least one wall spacer that at least partially surrounds the electrode structure.

13. The apparatus of claim 1, wherein:
the substrate comprises a substrate stack comprising an intermediate layer having a surface that faces a second surface of the electrode structure; and
the intermediate layer and the at least one spacer comprise a dielectric material or amorphous silicon.

14. The apparatus of claim 13, wherein:
the substrate stack comprises a substrate layer; and
the intermediate layer is disposed between the electrode structure and the substrate layer.

15. The apparatus of claim 14, wherein the substrate layer comprises at least one of the following materials:
silicon;
silicon dioxide;
silicon carbide;
sapphire; or
glass.

16. The apparatus of claim 1, wherein the microacoustic filter comprises an embedding layer disposed on the substrate between adjacent fingers of multiple fingers of the electrode structure such that the electrode structure is at least partially embedded within the embedding layer.

17. The apparatus of claim 16, wherein a thickness of the embedding layer is less than or equal to a thickness of the electrode structure.

18. The apparatus of claim 16, wherein the embedding layer comprises a dielectric material.

19. The apparatus of claim 1, wherein:
multiple fingers of the electrode structure are positioned across a first axis;
longitudinal axes of the multiple fingers are substantially parallel to a second axis that is perpendicular to the first axis;
a third axis is perpendicular to the first axis and the second axis;
an orientation of the first axis, the second axis, and the third axis is relative to a crystalline structure of the piezoelectric layer as defined by Euler angles lambda, mu, and theta; and
the piezoelectric layer comprises lithium niobate with a value of the Euler angle lambda being approximately 0°, a value of the Euler angle mu being approximately 32°, and a value of the Euler angle theta being approximately 0°, or at least one symmetrical equivalent thereof.

20. The apparatus of claim 1, wherein:
multiple fingers of the electrode structure are positioned across a first axis;
longitudinal axes of the multiple fingers are substantially parallel to a second axis that is perpendicular to the first axis;
a third axis is perpendicular to the first axis and the second axis;
an orientation of the first axis, the second axis, and the third axis is relative to a crystalline structure of the piezoelectric layer as defined by Euler angles lambda, mu, and theta; and
the piezoelectric layer comprises lithium niobate with the value of the Euler angle lambda being approximately 0°, the value of the Euler angle mu being approximately 0°, and the value of the Euler angle theta being approximately 90°, or at least one symmetrical equivalent thereof.

21. The apparatus of claim 1, wherein:
multiple fingers of the electrode structure are positioned across a first axis;
longitudinal axes of the multiple fingers are substantially parallel to a second axis that is perpendicular to the first axis;
a third axis is perpendicular to the first axis and the second axis;
an orientation of the first axis, the second axis, and the third axis is relative to a crystalline structure of the piezoelectric layer as defined by Euler angles lambda, mu, and theta; and
the piezoelectric layer comprises lithium tantalate with a value of the Euler angle lambda being approximately 0°, a value of the Euler angle mu being approximately 42°, and a value of the Euler angle theta being approximately 0°, or at least one symmetrical equivalent thereof.

22. The apparatus of claim 1, wherein:
the cavity is at least partially filled with a gas; and
the gas comprises air.

23. The apparatus of claim 1, wherein a resonance frequency associated with the plate mode is between approximately 2 and 20 gigahertz.

24. The apparatus of claim 23, wherein the resonance frequency associated with the plate mode is between approximately 7.5 and 17 gigahertz.

25. The apparatus of claim 1, wherein:
the microacoustic filter comprises multiple cascaded resonators; and
a resonator of the multiple cascaded resonators comprises the piezoelectric layer, the electrode structure, and the substrate.

26. The apparatus of claim 1, further comprising:
a wireless transceiver coupled to at least one antenna, the wireless transceiver comprising the microacoustic filter and configured to filter, using the microacoustic filter, a wireless signal communicated via the at least one antenna.

27. An apparatus comprising:
a microacoustic filter configured to generate a filtered signal from a radio-frequency signal, the microacoustic filter comprising:
a substrate;
means for producing a formed acoustic wave associated with a laterally-excited plate mode;
means for converting the radio-frequency signal to an acoustic wave and converting the formed acoustic wave into the filtered signal; and
means for separating the means for producing from the means for converting by forming a cavity between the means for producing and the means for converting.

28. The apparatus of claim 27, wherein the microacoustic filter comprises means for bonding the means for converting to the substrate.

29. The apparatus of claim 27, wherein the microacoustic filter comprises means for compensating for a decrease in a static capacitance associated with a separation distance between the means for producing and the means for converting, the means for compensating at least partially embedding the means for converting.

30. A method of manufacturing a microacoustic filter, the method comprising:
providing a piezoelectric layer having a crystalline structure operative to laterally excite a plate mode;
providing a substrate;
providing an electrode structure between the piezoelectric layer and the substrate, the electrode structure having a surface that faces the piezoelectric layer; and
providing at least one spacer extending from the substrate past a plane defined by the surface of the electrode structure and towards the piezoelectric layer to form a cavity between the electrode structure and the piezoelectric layer.

31. The method of claim 30, further comprising:
providing a dielectric material between the substrate and the piezoelectric layer, the dielectric material at least partially embedding the electrode structure.

32. A microacoustic filter comprising:
a piezoelectric layer having a crystalline structure operative to laterally excite a plate mode;
a substrate; and
an electrode structure that is positioned between the piezoelectric layer and the substrate, the electrode structure having a surface that faces the piezoelectric layer and is separated by a gap from the piezoelectric layer.

33. The microacoustic filter of claim 32, wherein a distance between the surface of the electrode structure and the piezoelectric layer is between approximately 2 and 200 nanometers.

34. The microacoustic filter of claim 32, further comprising:
an intermediate layer disposed between the electrode structure and the substrate, the intermediate layer comprising amorphous silicon or a dielectric.

35. The microacoustic filter of claim 34, wherein:
the microacoustic filter comprises at least one spacer disposed on the intermediate layer, the at least one spacer extending past a plane defined by the surface of the electrode structure; and
the at least one spacer comprises the amorphous silicon or the dielectric.

36. The microacoustic filter of claim 35, wherein:
the electrode structure comprises two busbars and multiple fingers; and
the at least one spacer is positioned between two fingers of the multiple fingers, the two fingers connected to a same busbar of the two busbars.

37. The microacoustic filter of claim 32, further comprising a dielectric material positioned between the substrate and the piezoelectric layer and at least partially embedding the electrode structure.

38. The microacoustic filter of claim 32, wherein:
the electrode structure comprises multiple fingers positioned across a first axis;
longitudinal axes of the multiple fingers are substantially parallel to a second axis that is perpendicular to the first axis;
a third axis is perpendicular to the first axis and the second axis;
an orientation of the first axis, the second axis, and the third axis is relative to the crystalline structure of the piezoelectric layer as defined by Euler angles lambda, mu, and theta; and
the piezoelectric layer comprises one of the following:
lithium niobate with a value of the Euler angle lambda being approximately 0°, a value of the Euler angle mu being approximately 32°, and a value of the Euler angle theta being approximately 0°, or at least one symmetrical equivalent thereof;
the lithium niobate with the value of the Euler angle lambda being approximately 0°, the value of the Euler angle mu being approximately 0°, and the value of the Euler angle theta being approximately 90°, or at least one symmetrical equivalent thereof; or
lithium tantalate with a value of the Euler angle lambda being approximately 0°, a value of the Euler angle mu being approximately 42°, and a value of the Euler angle theta being approximately 0°, or at least one symmetrical equivalent thereof.
